(19) United States
(12) Patent Application Publication
(10) Pub. No.: US 2025/0056939 A1
(43) Pub. Date: Feb. 13, 2025

(54) SOLID STATE LIGHT EMITTING COMPONENTS WITH UNITARY LENS STRUCTURES

(71) Applicant: CreeLED, Inc., Durham, NC (US)

(72) Inventor: Peter Scott Andrews, Durham, NC (US)

(21) Appl. No.: 18/456,877

(22) Filed: Aug. 28, 2023

Related U.S. Application Data
(63) Continuation of application No. PCT/US2023/071844, filed on Aug. 8, 2023.
(60) Provisional application No. 63/397,068, filed on Aug. 11, 2022.

(51) Int. Cl. H01L 33/58

(52) U.S. Cl. CPC H01L 33/58

(57) ABSTRACT

Solid state light emitting components include novel lens structures arranged in contact with at least one solid state light emitters, without an intervening air gap, to provide desirable combinations of output characteristics and dispensing with the need for secondary optics. A lens structure includes an inclined or curved surface having an orientation configured to produce total internal reflection (TIR) of light emissions toward light exit surfaces. A non-Lambertian lens structure is configured to produce focused output emissions or dispersed output emissions with specified distributions over angular ranges. A unitary lens structure may include a recess shaped as an inverted pyramid, an inverted cone, or a trench with a nadir that is registered with an emissive center of a solid state emitter, with walls configured to produce TIR.

### TECHNICAL FIELD

This application is a continuation of International Patent Application No. PCT/US2023/71844 filed on Aug. 8, 2023, which claims priority to U.S. Provisional Patent Application No. 63/397,068 filed on Aug. 11, 2022, wherein the entire contents of the foregoing applications are hereby incorporated by reference herein.

### TECHNICAL FIELD

Subject matter herein relates to solid state light-emitting devices incorporating unitary lens structures arranged over one or more solid state light emitters (e.g., light emitting diodes (LEDs) optionally combined with one or more lumiphors), and methods for fabricating such devices.

### BACKGROUND

Solid-state lighting devices such as light-emitting diodes (LEDs) are increasingly used in both consumer and commercial applications. LEDs have been widely adopted in various illumination contexts, as well as for backlighting of liquid crystal displays and for providing sequentially illuminated LED displays. Illumination applications include automotive headlamps, roadway lamps, stadium lights, light fixtures, flashlights, and various indoor, outdoor, and specialty lighting contexts. Desirable characteristics of LED devices according to various end uses include high luminous efficacy, uniform color point over an illuminated area, long lifetime, wide color gamut, and compact size.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, indium phosphide, aluminum nitride, gallium arsenide-based materials, and/or from organic semiconductor materials. Photons generated by the active region are initiated in all directions.

Lumiphoric materials, such as phosphors, may be arranged in light emission paths of LED emitters to convert portions of light to different wavelengths. LED packages have been developed that can provide mechanical support, electrical connections, and encapsulation for LED emitters. Light emissions that exit surfaces of LED emitters typically interact with lumiphoric materials and various elements or surfaces of the LED package before being emitted into an environment, thereby increasing opportunities for light loss (e.g., due to internal absorption) and potential non-uniformity of light emissions. As such, there can be challenges in producing high quality light with desired emission characteristics while also providing high luminous efficacy. LED packages frequently require secondary optics (e.g., lenses and/or reflectors, including metalized reflectors) to desired output beam characteristics, since the light emanating from the primary optic of a conventional LED package is typically too broad and lacks intensity over distance, however, secondary optics increase the size, cost, and complexity of lighting devices, and result in optical losses. Another limitation associated with LED lighting devices is long-term reliability, particularly when constituents thereof exhibit different thermal expansion characteristics and are subject to thermal loading with a large number of operating cycles.

The art continues to seek improved solid-state lighting devices having desirable illumination characteristics capable of overcoming challenges associated with conventional lighting devices, and methods for fabricating such devices.

### SUMMARY

The present disclosure relates in various aspects to solid state light emitting components including novel lens structures arranged in contact with one or more solid state light emitters (e.g., incorporating at least one LED chip optionally combined with a lumiphoric material over an outer surface thereof), to provide desirable combinations of output characteristics differing from those provided by conventional components. In certain embodiments, the lens structures dispense with the need for secondary optics. In embodiments that include a unitary lens structure, at least a first portion of the lens structure has a width that increases with distance away from the solid state light emitter(s), and includes an inclined or curved surface having an orientation configured to produce total internal reflection of at least a portion of light emissions toward one or light exit surface of the component. In certain embodiments, a non-Lambertian unitary lens structure is provided over at least one solid state light emitter without an intervening air gap therebetween, and the lens structure is configured to produce either (a) focused output emissions having an intensity distribution over an angular range with a full width at half maximum (FWHM) value of less than 100, or dispersed output emissions having an intensity distribution over an angular range with a FWHM value of greater than 130.

In certain embodiments, a unitary lens structure comprises a recess shaped as an inverted pyramid, an inverted cone, or a trench with a nadir that is registered with an emissive center of at least one solid state emitter, the recess being bounded by one or more inclined walls, wherein an axis extends through the nadir and the emissive center, and wherein the one or more inclined walls are inclined away from the axis by an angle in a range of from 40 to 44 degrees. In certain embodiments, a lens structure comprises a light spreading portion contacting the outer surface of the at least one solid state light emitter; and a compound index portion arranged over the light spreading portion, the compound index portion comprising a first region having a first index of refraction and a second region having a second index of refraction that differs from the first index of refraction, the first region covering less than an entirety of the light spreading portion.

In one aspect, the disclosure relates to a solid state light emitting component that comprises: at least one solid state light emitter configured to generate light emissions; and a unitary lens structure arranged in contact with the at least one solid state light emitter and configured to receive at least a portion of the light emissions generated by the at least one solid state light emitter; wherein at least a first portion of the unitary lens structure proximate to the at least one solid state light emitter has a width that increases with distance away from the at least one solid state light emitter; and wherein the at least a first portion of the unitary lens structure comprises at least one inclined or curved surface having an orientation configured to produce total internal reflection of a portion of light emissions originating from an emissive center of the at least one solid state light emitter, and configured to reflect light toward one or more light exit surfaces of the solid state light emitting component.

In certain embodiments, the at least one inclined or curved surface comprises a peripheral edge surface of the at least a first portion of the unitary lens structure.

In certain embodiments, the unitary lens structure defines a recess, and the at least one inclined or curved surface bounds at least a portion of the recess.

In certain embodiments, the unitary lens structure further comprises a second portion having a width that decreases with distance away from the at least one solid state light emitter, wherein the first portion of the unitary lens structure is arranged between the at least one solid state light emitter and the second portion of the unitary lens structure.

In certain embodiments, the second portion of the unitary lens structure comprises a proximal segment having a truncated pyramidal shape (e.g., having a top view profile that is square), and comprises a distal segment having a domed shape (e.g., having a top view profile that is round).

In certain embodiments, the unitary lens structure comprises a third portion having a round or square cross-sectional shape, wherein the third portion is arranged between the first portion and the second portion.

In certain embodiments, the unitary lens structure comprises a material having a first index of refraction, the at least a first portion of the unitary lens structure is bounded by an outer lateral lens surface, and the outer lateral lens surface is bounded by a material or space having a second index of refraction, wherein the first index of refraction exceeds the second index of refraction by a value of least 0.4.

In certain embodiments, the at least a first portion of the unitary lens structure comprises an inverted truncated pyramidal shape (e.g., having a square top view profile) or an inverted truncated conical shape (e.g., having a round top view profile).

In certain embodiments, the unitary lens structure comprises a recess shaped as an inverted pyramid, an inverted cone, or a trench, and having a nadir that is registered with the emissive center of the at least one solid state light emitter.

In certain embodiments, the one or more light exit surfaces are arranged along lateral edges of the unitary lens structure.

In certain embodiments, the solid state light emitting component further comprises a secondary lens structure arranged in contact with the unitary lens structure, wherein the unitary lens structure is arranged between the at least one solid state light emitter and the secondary lens structure.

In certain embodiments, the solid state light emitting component further comprises a submount to which the at least one solid state light emitter is mounted, wherein a width of the unitary lens structure is no greater than a width of the submount at a location where the unitary lens structure is arranged in contact with the at least one solid state light emitter.

In certain embodiments, the at least one solid state light emitter comprises a LED chip and a lumiphoric material layer arranged over an outer surface of the LED chip, wherein lateral edge surfaces of the LED chip are devoid of lumiphoric material, and the solid state light emitting component further comprises: a submount to which the at least one solid state light emitter is mounted; and a fill material layer comprising fill material and contacting lateral edge surfaces of the at least one solid state light emitter, the fill material comprising white or light-reflective particles dispersed in a binder; wherein a portion of the lumiphoric material overlaps a portion of the fill material layer.

In certain embodiments, the lumiphoric material layer, the fill material layer, and the unitary lens structure are substantially matched in coefficient of thermal expansion (CTE), such that a difference in CTE between any two or more of the lumiphoric material layer, the fill material layer, and the lens material is in a range of less than 20%.

In certain embodiments, the unitary lens structure comprises silicone.

In another aspect, the disclosure relates to a solid state light emitting component that comprises: at least one solid state light emitter configured to generate light emissions; and a non-Lambertian unitary lens structure arranged in contact with the at least one solid state light emitter and configured to receive at least a portion of the light emissions generated by the at least one solid state light emitter, wherein the solid state light emitting component is devoid of an air gap through which the light emissions are transmitted into the non-Lambertian unitary lens structure; wherein the non-Lambertian unitary lens structure is configured to shape light emissions received from the at least one solid state light emitter to produce output emissions having one of the following characteristics (a) or (b): (a) focused output emissions having an intensity distribution over an angular range with a full width at half maximum (FWHM) value of less than 100, or (b) dispersed output emissions having an intensity distribution over an angular range with a FWHM value of greater than 130. In this context, FWHM refers to the difference between the two values of the independent variable at which the dependent variable is equal to half of its maximum value (restated, it is the width of a spectrum curve measured between those points on the y-axis which are half the maximum amplitude).

In certain embodiments, the non-Lambertian unitary lens structure is configured to shape light emissions received from the at least one solid state light emitter to produce focused output emissions having an intensity distribution over an angular range with a FWHM value in a range between 40 and 100.

In certain embodiments, the non-Lambertian unitary lens structure is configured to shape light emissions received from the at least one solid state light emitter to produce dispersed output emissions having an intensity distribution over an angular range with a FWHM value in a range between 130 and 200.

In certain embodiments, at least a first portion of the non-Lambertian unitary lens structure proximate to the at least one solid state light emitter has a width that increases with distance away from the at least one solid state light emitter; and the at least a first portion of the non-Lambertian unitary lens structure is bounded by a lateral edge surface having an orientation configured to produce total internal reflection of a portion of light emissions originating from an emissive center of the at least one solid state light emitter.

In certain embodiments, the at least one solid state light emitter is arranged within a cavity defined by an elevated reflector structure; at least a first portion of the non-Lambertian unitary lens structure proximate to the at least one solid state light emitter has a width that increases with distance away from the at least one solid state light emitter; and the at least a first portion of the non-Lambertian unitary lens structure is arranged in contact with a reflective wall of the elevated reflector structure bounding the cavity.

In certain embodiments, the elevated reflector structure comprises light reflective particles suspended within a binder; the non-Lambertian unitary lens structure comprises a lens material; and the elevated reflector structure and the lens material are substantially matched in coefficient of thermal expansion (CTE), such that a CTE difference therebetween is in a range of less than 20%.

In certain embodiments, the solid state light emitting component further comprises a submount to which the at least one solid state light emitter is mounted, wherein a width of the non-Lambertian unitary lens structure is no greater than a width of the submount at a location where the non-Lambertian unitary lens structure is arranged in contact with the at least one solid state light emitter.

In certain embodiments, the at least one solid state light emitter comprises a LED chip and a lumiphoric material layer arranged over an outer surface of the LED chip, wherein lateral edge surfaces of the LED chip are devoid of lumiphoric material, and the solid state light emitting component further comprises: a submount to which the at least one solid state light emitter is mounted; and a fill material layer comprising fill material and contacting lateral edge surfaces of the at least one solid state light emitter, the fill material comprising white or light-reflective particles dispersed in a binder; wherein a portion of the lumiphoric material overlaps a portion of the fill material layer.

In certain embodiments, the lumiphoric material layer, the fill material layer, and the non-Lambertian unitary lens structure are substantially matched in coefficient of thermal expansion (CTE), such that a difference in CTE between any two or more of the lumiphoric material layer, the fill material layer, and the lens material is in a range of less than 20%.

In certain embodiments, the non-Lambertian unitary lens structure comprises silicone.

In another aspect, the present disclosure relates to a solid state light emitting component that comprises: at least one solid state light emitter configured to generate light emissions, the at least one solid state having an emissive center; and a unitary lens structure arranged in contact with the at least one solid state light emitter and configured to receive at least a portion of the light emissions generated by the at least one solid state light emitter; wherein the unitary lens structure comprises a recess shaped as an inverted pyramid, an inverted cone, or a trench with a nadir that is registered with the emissive center, the recess being bounded by one or more inclined walls, wherein an axis extends through the nadir and the emissive center, and wherein the one or more inclined walls are inclined away from the axis by an angle in a range of from 40 to 44 degrees.

In certain embodiments, the unitary lens structure comprises one of more light exit surfaces along lateral edges thereof, and wherein the one or more inclined walls are configured to reflect light toward the one or more light exit surfaces.

In certain embodiments, the unitary lens structure comprises a material having a first index of refraction, and wherein the recess is substantially filled with a material having a second index of refraction that differs from the first index of refraction by at least 0.4.

In certain embodiments, the material having a second index of refraction comprises air.

In certain embodiments, at least a first portion of the unitary lens structure proximate to the at least one solid state light emitter has a width that increases with distance away from the at least one solid state light emitter; and the at least a first portion of the unitary lens structure is laterally bounded by at least one inclined or curved surface having an orientation configured to produce total internal reflection of a portion of light emissions originating from an emissive center of the at least one solid state light emitter.

In certain embodiments, the unitary lens structure defines first and second lobes, and the recess is shaped as a trench arranged between the first and second lobes.

In certain embodiments, each of the first lobe and the second lobe comprises a light emitting surface, and at least a portion of light emitting surface has an outwardly curved or convex profile.

In certain embodiments, the solid state light emitting component further comprises a submount to which the at least one solid state light emitter is mounted, wherein a width of the unitary lens structure is no greater than a width of the submount at a location where the unitary lens structure is arranged in contact with the solid state light emitter.

In certain embodiments, the at least one solid state light emitter comprises a LED chip and a lumiphoric material layer arranged over an outer surface of the LED chip, wherein lateral edge surfaces of the LED chip are devoid of lumiphoric material, and the solid state light emitting component further comprises: a submount to which the at least one solid state light emitter is mounted; and a fill material layer comprising fill material and contacting lateral edge surfaces of the at least one solid state light emitter, the fill material comprising white or light-reflective particles dispersed in a binder; wherein a portion of the lumiphoric material overlaps a portion of the fill material layer.

In certain embodiments, the lumiphoric material layer, the fill material layer, and the unitary lens structure are substantially matched in coefficient of thermal expansion (CTE), such that a difference in CTE between any two or more of the lumiphoric material layer, the fill material layer, and the lens material is in a range of less than 20%.

In another aspect, the present disclosure relates to a solid state light emitting component that comprises: at least one solid state light emitter arranged over a submount and configured to generate light emissions, the at least one solid state light emitter comprising an outer surface distal from the submount; and a lens structure arranged over the at least one solid state light emitter and configured to receive at least a portion of the light emissions generated by the at least one solid state light emitter, the lens structure comprising: a light spreading portion contacting the outer surface of the at least one solid state light emitter; and a compound index portion arranged over the light spreading portion, the compound index portion comprising a first region having a first index of refraction and a second region having a second index of refraction that differs from the first index of refraction, the first region covering less than an entirety of the light spreading portion.

In certain embodiments, the light spreading portion of the lens comprises a width that increases with distance away from the at least one solid state light emitter, and is laterally bounded by at least one inclined or curved surface having an orientation configured to produce total internal reflection of a portion of light emissions originating from an emissive center of the at least one solid state light emitter and configure to reflect light toward one or more light exit surfaces of the lens structure.

In certain embodiments, the first region of the compound index portion comprises glass or sapphire.

In certain embodiments, the first region of the compound index portion consists of air or at least one gas.

In certain embodiments, the solid state light emitting device further comprises a submount to which the at least one solid state light emitter is mounted, wherein a width of the unitary lens structure is no greater than a width of the submount at a location where the unitary lens structure is arranged in contact with the at least one solid state light emitter.

In certain embodiments, the at least one solid state light emitter comprises a LED chip and a lumiphoric material layer arranged over an outer surface of the LED chip, wherein lateral edge surfaces of the LED chip are devoid of lumiphoric material, and the solid state light emitting component further comprises: a submount to which the at least one solid state light emitter is mounted; and a fill material layer comprising fill material and contacting lateral edge surfaces of the at least one solid state light emitter, the fill material comprising white or light-reflective particles dispersed in a binder; wherein a portion of the lumiphoric material overlaps a portion of the fill material layer.

In certain embodiments, the light spreading portion of the lens comprises a width that increases with distance away from the at least one solid state light emitter, and is laterally bounded by at least one inclined or curved surface having an orientation configured to produce total internal reflection of a portion of light emissions originating from an emissive center of the at least one solid state light emitter and configured to reflect light toward one or more light exit surfaces of the lens structure.

In certain embodiments, the first region of the compound index portion comprises glass or sapphire, or the first region of the compound index portion consists of air or at least one gas.

In certain embodiments, the solid state light emitting device further comprises a submount to which the at least one solid state light emitter is mounted, wherein a width of the unitary lens structure is no greater than a width of the submount at a location where the unitary lens structure is arranged in contact with the at least one solid state light emitter.

In certain embodiments, wherein the at least one solid state light emitter comprises a LED chip and a lumiphoric material layer arranged over an outer surface of the LED chip, wherein lateral edge surfaces of the LED chip are devoid of lumiphoric material, and the solid state light emitting component further comprises: a submount to which the at least one solid state light emitter is mounted; and a fill material layer comprising fill material and contacting lateral edge surfaces of the at least one solid state light emitter, the fill material comprising white or light-reflective particles dispersed in a binder; wherein a portion of the lumiphoric material overlaps a portion of the fill material layer.

In certain embodiments, the lumiphoric material layer, the fill material layer, and the light spreading portion of the lens structure are substantially matched in coefficient of thermal expansion (CTE), such that a difference in CTE between any two or more of the lumiphoric material layer, the fill material layer, and the light spreading portion is in a range of less than 20%.

In another aspect, any of the foregoing aspects, and/or various separate aspects and features as described herein, may be combined for additional advantage. Any of the various features and elements as disclosed herein may be combined with one or more other disclosed features and elements unless indicated to the contrary herein.

Other aspects, features and embodiments of the present disclosure will be more fully apparent from the ensuing disclosure and appended claims.

### BRIEF DESCRIPTION OF THE DRAWINGS

FIG. 1 is a simplified cross-sectional view of a first conventional solid state light emitting device including a LED chip supported by a submount, with a lumiphoric material layer covering upper surfaces of the LED chip and the submount, and covering side surfaces of the LED chip, with reflective material arranged on portions of the lumiphoric material layer, and with superimposed arrows showing selected light beams emanating from an emissive center of the LED chip.

FIG. 2 is a simplified cross-sectional view of a second conventional solid state light emitting device including a LED chip supported by a submount, with a lumiphoric material layer covering upper and side surfaces of the LED chip, and with reflective material arranged on the submount and side surface portions of the lumiphoric material layer.

FIGS. 3A-3F are simplified cross-sectional views depicting steps utilizing a sealing template in producing at least a portion of solid state light emitting device (or subassembly) according to one embodiment, the device portion having a light-altering (e.g., lumiphoric) material layer arranged over an upper surface of a LED chip supported by a submount and over portions of a first fill material layer that contacts lateral edges of the LED chip, with a second fill material layer contacting lateral edges of the lumiphoric material layer.

FIG. 3G is a simplified cross-sectional view of a solid state light emitting device incorporating the device portion of FIG. 3F following formation of a lens material having an outwardly curved shape over the lumiphoric material layer and portions of the second fill material layer.

FIGS. 3H-3I are simplified cross-sectional views depicting further steps in producing a solid state light emitting device incorporating the device portion of FIG. 3F including formation of a cavity-defining elevated reflector structure arranged over the second fill material layer, and formation of a lens material having an outwardly curved shape contacting the lumiphoric material layer and walls of the elevated reflector structure.

FIG. 4 is a simplified cross-sectional view of a solid state light emitting device according to one embodiment, including a LED chip supported by a substrate, first fill material contacting lateral boundaries of the LED chip, a lumiphoric material layer contacting an upper surface of the LED chip and portions of the first fill material, a cavity-defining elevated reflector structure arranged over the first fill material layer, and lens material having a substantially hemispherical shape contacting walls of the elevated reflector structure and contacting the lumiphoric material layer, being suitable for producing focused light output emissions.

FIG. 5 is a simplified cross-sectional view of a portion of solid state light emitting device similar to that shown in FIG. 4, but with the lens material having a flat shape substantially registered with an upper boundary of the elevated reflector structure and suitable for producing dispersed light output emissions.

FIG. 6 is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens including a lower portion bounded by a lateral edge having a width that increases with distance away from the LED chip and configured to produce total internal reflection of light emissions originating from an emissive center of the LED chip, and with an upper portion of the lens having a substantially hemispherical shape.

FIG. 7A is a simplified cross-sectional view of a solid state light emitting device according to one embodiment similar to that shown in FIG. 6, but with the upper portion of the lens having a (flattened) partially spherical shape.

FIG. 7B is a modeled ray trace diagram showing a pattern of light beams produced by a solid state light emitting device according to the design of FIG. 7A.

FIG. 8A is a simplified cross-sectional view of a solid state light emitting device according to one embodiment including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens including a lower portion bounded by a lateral edge having a width that increases with distance away from the LED chip and configured to produce total internal reflection of light emissions originating from an emissive center of the LED chip, the lens including an upper portion of the lens having width that decreases with distance to a small radius tip, with a curved profile transition between the lower and upper portions of the lens.

FIG. 8B is a modeled ray trace diagram showing a pattern of light beams produced by a solid state light emitting device according to the design of FIG. 8A.

FIG. 9A is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens including a lower portion bounded by a lateral edge having a width configured to produce total internal reflection of light emissions originating from an emissive center of the LED chip, and including an upper portion of the lens having a width that decreases with distance away from the LED chip and terminates at a flat upper boundary, wherein a curved profile transition is provided at an interface between the upper and lower portions of the lens.

FIG. 9B is a modeled ray trace diagram showing a pattern of light beams produced by a solid state light emitting device similar to the design of FIG. 9A.

FIG. 10 is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens including a lower portion bounded by a lateral edge having a width configured to produce total internal reflection of light emissions originating from an emissive center of the LED chip, and including an upper portion of the lens having a width that decreases with distance away from the LED chip, with a sharp boundary between the upper and lower portions of the lens.

FIG. 11A is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens including a lower portion bounded by a lateral edge having a width configured to produce total internal reflection of light emissions originating from an emissive center of the LED chip, and with an upper portion of the lens having a width that decreases with distance away from the LED chip and terminating with a rounded upper boundary, wherein the lower portion has a profile when viewed from above (i.e., a top view profile) that appears square and the upper portion has top view profile that is round, with a transition from square top profile to rounded top profile therebetween.

FIG. 11B shows the solid state light emitting device of FIG. 11A having superimposed thereon a partial ray trace diagram showing light beams emanating from three positions along an upper surface of the LED chip.

FIG. 12 is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens having a width substantially greater than a width of the substrate, the lens including a lower portion bounded by a lateral edge having a width that increases with distance away from the LED chip and configured to produce total internal reflection of light emissions originating from an emissive center of the LED chip, and the lens including an upper portion having a substantially hemispherical shape.

FIG. 13A is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens bounded by a lateral edge having a width that increases with distance away from the LED chip according to a curved profile and configured to produce total internal reflection of light emissions originating from an emissive center of the LED chip, the lens further including a flat upper boundary.

FIG. 13B is a partial ray trace diagram for an idealized lens similar to the lens of the solid state light emitting device of FIG. 13A, but including a continuous curved (instead of truncated curved) base.

FIG. 14A is a simplified cross-sectional view of a solid state light emitting device according to an embodiment similar to that shown in FIG. 13A, further including a constant width portion of the lens arranged distal from the LED chip.

FIG. 14B is a partial ray trace diagram an idealized lens similar to the lens of the solid state light emitting device of FIG. 14A, but including a continuous curved (instead of truncated curved) base.

FIG. 15 is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens including a first portion proximate to the LED chip bounded by a lateral edge having a width that increases with distance away from the LED chip according to a curved profile and configured to produce total internal reflection of light emissions originating from an emissive center of the LED chip, and the lens including a second portion distal from the LED chip bounded by a lateral edge having a width that increases with distance away from the LED chip according to a curved profile, with the first and second lens portions being partially or substantially hemispherical in shape.

FIG. 16 is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens defining a conical recess having a point proximate to the LED chip.

FIG. 17A is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens defining a variable diameter central recess therein shape, wherein angled surfaces of the central recess are configured to produce total internal reflection of light to direct light emissions toward lateral edges of the lens.

FIG. 17B is a modeled ray trace diagram showing a pattern of light beams produced by the solid state light emitting device of FIG. 17A when positioned in an upward direction.

FIG. 18A is a cross-sectional view of the solid state light emitting device of FIG. 17A arranged within the cavity of a secondary reflector structure.

FIG. 18B is a modeled ray trace diagram showing a pattern of light beams produced by the solid state light emitting device and secondary reflector structure of FIG. 18A.

FIG. 19 is a modeled ray trace diagram showing a pattern of light beams produced by a solid state light emitting device similar to that shown in FIG. 17A, but stretched in width and positioned in a downward direction.

FIG. 20 is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens including first and second lobes bounding a central trench and each having an outwardly curved light extraction surface.

FIG. 21 is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, with the lens including a first portion proximate to the LED chip bounded by a lateral edge having a width that increases with distance away from the LED chip and configured to produce total internal reflection of light emissions originating from an emissive center of the LED chip, with the lens including a second portion distal from the LED chip bounded by a lateral edge having constant width, and with an internal region (e.g., air) having a hemispherical shape and an index of refraction differing from the lens material arranged between the first and second portions of the lens.

FIG. 22A is a simplified cross-sectional view of a solid state light emitting device according to one embodiment, including a LED chip supported by a substrate, a lumiphoric material layer contacting an upper surface of the substrate, at least one fill material contacting lateral boundaries of the LED chip and lumiphoric material layer, and a unitary lens structure arranged in contact with the lumiphoric material layer and the at least one fill material, the lens including a first portion proximate to the LED chip bounded by a lateral edge having a width that increases with distance away from the LED chip and configured to produce total internal reflection of light emissions originating from an emissive center of the LED chip, the lens including a second portion having a sawtooth-shaped sidewall profile distal from the LED chip, and the lens defining a central recess therein extending to a nadir proximate to the LED chip.

FIG. 22B is a first modeled ray trace diagram showing a low-density pattern of light beams produced by the solid state light emitting device of FIG. 22A.

FIG. 23A provides plots of viewing angle (full width at half maximum degrees) for multiple samples of a solid state light emitting device (“V9Flat”) having a flat lens, reflector cavity, LED chip, and lumiphoric material arrangement according to FIG. 5, and for multiple samples of a comparison device (“XPGB+”) having a hemispherical lens arrangement deposited on a base structure including lumiphoric material arranged on lateral edge surfaces of a LED chip and between a submount and a reflective fill material (similar to FIG. 1).

FIG. 23B provides bivariate fits of intensity (in candela) as a function of viewing angle (theta) for the same solid state light emitting devices and comparison devices of FIG. 23A.

FIG. 23C provides bivariate first of change in correlated color temperature (dCCT_c) as a function of viewing angle (theta) for the same solid state light emitting devices and comparison devices of FIG. 23A.

FIG. 24A provides plots of viewing angle (full width at half maximum degrees) for multiple samples of a solid state light emitting device (“V29”) according to FIG. 11A, and for multiple samples of a comparison device (“XPGB+”) having a similar lens arrangement but including lumiphoric material arranged on lateral edge surfaces of a LED chip and between a submount and a reflective fill material (similar to FIG. 1).

FIG. 24B provides viewing angle mean and standard deviation values for the same solid state light emitting devices and comparison devices of FIG. 24A.

FIG. 24C provides bivariate fits of intensity (in candela) as a function of viewing angle (theta) for the same solid state light emitting devices and comparison devices of FIG. 24A.

FIG. 24D provides bivariate fits of relative intensity (dimensionless) as function of viewing angle (theta) for the same solid state light emitting devices and comparison devices of FIG. 24A, derived from the intensity data plotted in FIG. 24C.

FIG. 25A provides plots of viewing angle (full width at half maximum degrees) for multiple samples of solid state light emitting devices (“V41V40”) having an outwardly curved lens and lumiphoric material arrangement according to FIG. 7A, and for multiple samples of a comparison device (“XPGB+”) having a similar lens arrangement but including lumiphoric material arranged on lateral edge surfaces of a LED chip and between a submount and a reflective fill material (similar to FIG. 1).

FIG. 25B provides viewing angle mean and standard deviation values for the same solid state light emitting devices and comparison devices of FIG. 25A.

FIG. 25C provides bivariate fits of luminous flux corrected by color point (CCx) for the same solid state light emitting devices and comparison devices of FIG. 25A.

FIG. 25D provides bivariate fits of intensity (in candela) as a function of viewing angle (theta) for the same solid state light emitting devices and comparison devices of FIG. 25A.

FIG. 25E provides bivariate fits of relative intensity (dimensionless) as function of viewing angle (theta) for the same solid state light emitting devices and comparison devices of FIG. 25A, derived from the intensity data plotted in FIG. 26D.

FIG. 25F provides bivariate fits of change of correlated color temperature (dCCT_c) as function of viewing angle (theta) for the same solid state light emitting devices and comparison devices of FIG. 25A.

FIG. 26A provides plots of viewing angle (full width at half maximum degrees) for multiple samples of solid state light emitting devices (“V241nvCone”) having a conical shaped recess defined in a unitary lens arranged over a LED chip and lumiphoric material arrangement according to FIG. 17A, and for multiple samples of a comparison device (“XPGB+”) having a similar lens arrangement but including lumiphoric material arranged on lateral edge surfaces of a LED chip and between a submount and a reflective fill material (similar to FIG. 1).

FIG. 26B provides bivariate fits of intensity (in candela) as a function of viewing angle (theta) for the same solid state light emitting devices and comparison devices of FIG. 26A.

FIG. 26C provides bivariate fits of relative intensity (dimensionless) as function of viewing angle (theta) for the same solid state light emitting devices and comparison devices of FIG. 26A.

FIG. 26D provides bivariate fits of change of correlated color temperature (dCCT_c) as function of viewing angle (theta) for the same solid state light emitting devices and comparison devices of FIG. 26A.

FIG. 27A provides plots of viewing angle (full width at half maximum degrees) for multiple samples of a solid state light emitting device (“V8Dome”) having a hemispherical lens, reflector cavity, LED chip, and lumiphoric material arrangement according to FIG. 4, and for multiple samples of a comparison device (“XPGB+”) having a hemispherical lens arrangement deposited on a base structure including lumiphoric material arranged on lateral edge surfaces of a LED chip and between a submount and a reflective fill material (similar to FIG. 1).

FIG. 27B provides viewing angle mean and standard deviation values for the same solid state light emitting devices and comparison devices of FIG. 27A.

FIG. 27C provides bivariate fits of intensity (in candela) as a function of viewing angle (theta) for the same solid state light emitting devices and comparison devices of FIG. 27A.

FIG. 27D provides bivariate fits of relative intensity (dimensionless) as function of viewing angle (theta) for the same solid state light emitting devices and comparison devices of FIG. 27A.

FIG. 27E provides bivariate fits of change of correlated color temperature (dCCT_c) as function of viewing angle (theta) for the same solid state light emitting devices and comparison devices of FIG. 27A.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Before delving into specific details of various aspects of the present disclosure, an overview of various elements that may be included in exemplary LEDs of the present disclosure is provided for context. A LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), indium phosphide (InP), and related compounds.

The active LED structure may be grown on a growth substrate that can include many materials, such as sapphire, SiC, aluminum nitride (AlN), GaN, GaAs, glass, or silicon. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. In certain embodiments, the active LED structure may be configured to emit light that is outside the visible spectrum, including one or more portions of the ultraviolet (UV) spectrum.

A LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. A LED source and one or more lumiphoric materials may be selected such that their combined output results in light with one or more desired characteristics such as color, color point, intensity, spectral density, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak wavelengths may be used. In certain embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{1-x-y}SrₓEu_{y}AlSiN₃) emitting phosphors, and combinations thereof. In other embodiments, the LED chip and corresponding lumiphoric material may be configured to primarily emit converted light from the lumiphoric material so that aggregate emissions include little to no perceivable emissions that correspond to the LED chip itself.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

LED packages may include one or more elements, such as lumiphoric materials and electrical contacts, among others, that are provided with one or more LED chips on a support member, such as a submount or a lead frame. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure. Light-altering materials may be arranged within LED packages to reflect or otherwise redirect light from the one or more LED chips in a desired emission direction or pattern.

As used herein, “light-altering materials” may include many different materials including light-reflective materials that reflect or redirect light, that scatter light, light-absorbing materials that absorb light, lumiphoric materials, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. In certain aspects, the particles may have an index or refraction that is configured to refract light emissions in a desired direction. In certain aspects, light-reflective particles may also be referred to as light-scattering particles. A weight ratio of the light-reflective particles or scattering particles to a binder may comprise a range of about 0.15:1 to about 0.5:1, or in a range of about 0.5:1 to about 1:1, or in a range of about 1:1 to about 2:1, depending on a desired viscosity before curing. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Solid state light emitting devices disclosed herein according to various embodiments include a lens structure arranged over a base portion or subassembly, wherein the base portion or subassembly includes at least one solid state emitter mounted over a submount, with at least one fill material contacting lateral edges of the at least one solid state emitter. The at least one solid state emitter may include a LED chip mounted over a submount, or may include a LED chip overlaid with a lumiphoric material and mounted over a submount. In the latter case, LED mounted over a submount having a first surface, a lumiphoric material layer applied over an entirety of an outer surface of the at least one LED that is distal from (i.e., opposing) the first surface, wherein lateral edges of the at least one LED are devoid of a lumiphoric material and at least one fill material layer contacting lateral surfaces of the at least one LED (wherein a fill material layer may also be in contact with lateral boundaries of the lumiphoric material layer). In certain embodiments, a base portion or subassembly may be fabricated by steps including applying a fill material layer to contact lateral surfaces of at least one LED mounted on a submount, adhering a sealing template on or over the fill material, and applying a lumiphoric material through a window defined in the sealing template to form a light-altering material layer on the at least one LED, and removing the sealing template from the fill material.

Prior templates (e.g., stencil templates, three-dimensionally printed templates, and the like) used or tested by the Applicant suffered from various shortcomings that limited their utility—such as either allowing light-altering material to pass between the template and underlying layer(s), or tending to cause light-altering material to stick to template walls, leading to poor control of areas where light-altering material would remain on underlying layer(s). However, local deposition of phosphor material over a LEDs arranged on a substrate without use of a template is also difficult, since a surface effects (e.g., surface tension tending to lead to meniscus formation) tend to prevent phosphor mixtures from covering entire emitting areas of LED (including corners thereof), and/or tend to form domed phosphor deposits with uneven thickness (i.e., having a thickness greater in a center of a LED chip than proximate to edges thereof).

In certain embodiments, a sealing template comprises a carrier layer (e.g., a film) and an adhesive layer, which may be provided in the form of an adhesive tape. In certain embodiments, the carrier layer be configured to transmit ultraviolet (UV) spectrum emissions, and the adhesive layer may comprise a UV release adhesive that exhibits a reduction or loss of tack upon exposure of the adhesive to UV spectrum emissions. One or more windows may be defined in the sealing template by any suitable method, such as laser cutting, blade cutting, stamping, pressing, or the like.

In certain embodiments, a window-defining template may be applied to an underlying layer (e.g., with windows in the template registered with one or more LEDs supported by the underlying layer) by pressing with sufficient force to cause the adhesive layer to engage the underlying layer. Thereafter, lumiphoric material may be applied through the windows (e.g., by spraying, dispensing, jet pumping, or other deposition methods). In certain embodiments, a sealing template may comprise a thickness substantially equal to a desired deposition thickness of the lumiphoric material. Optionally, any excess thickness of lumiphoric material may be removed by dragging a skimming member (e.g., a silicone or rubber blade, such as a squeegee) across an outer surface of the sealing template.

After deposition of lumiphoric material, the template may be exposed to UV emissions to cause an adhesive layer of the template to exhibit reduced tack. Thereafter, the template may be removed from the underlying layer by pulling (e.g., from an edge thereof), to cause lumiphoric material previously deposited through windows in the template to remain on a target surface after the template is removed. The ability to reduce tack of an adhesive layer after material deposition is complete enables a sealing template to be cleanly released from an underlying layer, without leaving adhesive residue, and without causing unintended removal of lumiphoric material that otherwise would be laterally adhered to edges of windows of the sealing template. Providing lumiphoric material solely in intended areas promotes attainment of uniform color point over an entire emissive area, and may improve brightness level and/or uniformity. In certain embodiments, multiple lumiphoric material layers may be applied in sequence, in the same (overlapping) are or different (non-overlapping) areas, including through a single window of a sealing template or through different windows defined in a multi-window sealing template.

After formation of a base portion or subassembly incorporating at least one solid state light emitter, a lens may be formed or otherwise applied over the solid state light emitter(s) and any surrounding fill material layer(s), optionally after an elevated reflector structure is formed on the base portion or subassembly. In certain embodiments, a lens may be formed directly on the base portion or subassembly by molding, three-dimensional printing, jet pumping, localized dispensation, or the like. In certain embodiments, an elevated reflector structure defining a cavity may be formed over a base portion or subassembly, and at least a portion of a lens may be deposited into the cavity. In certain embodiments, a lens may be prefabricated (e.g., by molding, cleaving, cutting, machining, or other fabrication methods) in one or more parts, and applied together or separately to a base portion or subassembly with a suitable adhesive (e.g., optical grade silicone adhesive). In certain embodiments, a portion or an entirety of a lens may comprise silicone, and may be fabricated by techniques such as molding. In certain embodiments, a portion or an entirety of a lens may comprise an amorphous or crystalline rigid material (e.g., glass, sapphire, or the like), and may be fabricated by cleaving, cutting, or machining, then adhered to an underlying structure. In certain embodiments, at least a portion of a lens may be prefabricated, applied to an underlying base material or subassembly, and a molding step may be performed thereafter to facilitate attachment and/or form any additional mold portions, wherein the foregoing method may be referred to as “pick and place and mold.” In certain embodiments, at least a portion of a prefabricated lens may be applied to an underlying base portion or subassembly, and then flooded (e.g., along at least a lower peripheral portion thereof) with silicone or silicone loaded with titanium dioxide or another reflective material, wherein the foregoing method may be referred to as “pick and place and flood”. A “pick and place and flood” method beneficially avoids formation of any mold flash, and may therefore promote improved manufacturability.

In certain embodiments, a lens is unitary in character, meaning that it embodies a single continuous structure. In certain embodiments, a unitary lens is fabricated as one member, whereas in certain other embodiments, a unitary lens may be fabricated as multiple members that are joined (e.g., bonded or adhered) to one another. In certain embodiments, a unitary lens is non-Lambertian. A Lambertian lens tends to diffuse or scatter light equally in all directions, instead of directing light in a specular direction. The apparent brightness or radiance of a Lambertian surface to an observer is the same regardless of the observer's viewing direction or viewing angle. In this regard, a non-Lambertian lens serves to direct light in a specular direction without diffusing light in all directions.

In certain embodiments, a lens incorporates one or more surfaces (e.g., inclined or curved surfaces) having an orientation configured to produce total internal reflection (TIR) of a portion of light emissions originating from an emissive center of at least one solid state light emitter of a solid state light emitting component, and configured to direct light toward one or more light exit surfaces of a solid state light emitting component. TIR is the optical phenomenon in which waves arriving at the interface (or boundary) from a first medium to a second medium another are not refracted into the second medium, but are completely reflected back into the first medium. TIR occurs when the second medium has a lower refractive index than the first medium, and waves are incident on the inter-medium interface at a sufficiently oblique angle (known as the critical angle). As some examples, optical grade silicone and glass have refractive indicates of about 1.5; air has a refractive index of about 1; and water has a refractive index of about 1.33. The first and second media may be independently selected from solids, liquids, and gases. For visible light, the critical angle is about 49° for incidence from water into air, about 42° for incidence from common glass to air, and about 41.8° for incidence from optical grade silicone into air. In certain embodiments, one or more surfaces of a lens configured to produce TIR of emissions of a solid state light emitter are bounded by air, or bounded by a solid material having a refractive index that differs from a refractive index of the lens material.

In certain embodiments, at least a first portion of a lens proximate to at least one solid state light emitter has a width that increase with distance away from the solid state light emitter(s). Such a portion of a lens may constitute a light spreading region. In certain embodiments, additional (e.g., second, third, etc.) portions of a lens providing different light directing or light shaping functions may be provided (e.g., joined to) the first portion.

In certain embodiments, an inclined or curved surface of a lens configured to produce TIR of emissions of a solid state light emitter comprises a peripheral edge surface of the at least a first portion of a lens (i.e., having a width that increase with distance away from the solid state light emitter).

In certain embodiments, a unitary lens structure defines a recess, and an inclined or curved surface of a lens configured to produce TIR of emissions of a solid state light emitter bounds at least a portion of the recess or trench. In such an embodiment, the inclined or curved surface of the lens may be configured to direct light emissions toward one or more light exit surfaces arranged at lateral edges (e.g., sides) of the lens structure. While recesses of various shapes are within the scope of the present disclosure, in certain embodiments a recess may be shaped as an inverted pyramid, an inverted cone, or a trench (e.g., having a substantially V-shaped or U-shaped cross-section). A recess may be formed by any suitable method such as molding, machining, water jet cutting, laser ablation, chemical processing, or the like.

In certain embodiments, a unitary lens structure may include a first portion proximate to a solid state light emitter has a width that increase with distance away from the solid state light emitter, and the unitary lens structure further defines a recess, wherein first inclined or curved surfaces configured to produce TIR of emissions of the solid state emitter may be provided at peripheral edge surfaces of the first portion, and second inclined or curved surfaces configured to produce TIR of emissions of the solid state emitter may be arranged to bound the recess.

In certain embodiments, a unitary lens structure is arranged in physical contact with at least one solid state light emitter (e.g., either a surface of a LED chip or a lumiphoric material layer coated on a LED chip, optionally segregated by one or more optically clear material layers). The foregoing feature provides one basis for differentiating secondary optics of conventional solid state devices, since such optics generally are not in direct contact with solid state light emitters. In certain embodiments, a solid state light emitter is mounted to a submount, and a unitary lens comprises a width that is no greater than a width of the submount at a chip mounting region where the unitary lens structure is arranged in contact with the at least one solid state light emitter. This provides another basis for differentiating conventional secondary optics, which are generally larger in width than an associated solid state light emitting component. In certain embodiments, a unitary lens structure is substantially matched in coefficient of thermal expansion (CTE), with underlying items such as a lumiphoric material layer and/or a fill material layer, such that a difference in CTE between any two or more of the lumiphoric material layer, the fill material layer, and the lens material is in a range of less than 20%. In certain embodiments, substantial CTE matching may be achieved by forming the lens material, lumiphoric material, and the fill material of the same base material (e.g., a binder material such as silicone, epoxy, or another polymeric material), wherein the lumiphoric material layer may have lumiphoric particles dispersed in binder material, the fill material may have reflective particles dispersed in binder material, and the lens material may consist essentially of binder material without light altering particles therein). This CTE matching may enhance reliability and service life of high-intensity solid state light emitting devices. Substantial CTE matching between lens material and underlying layers provides another potential basis for differentiating conventional secondary optics.

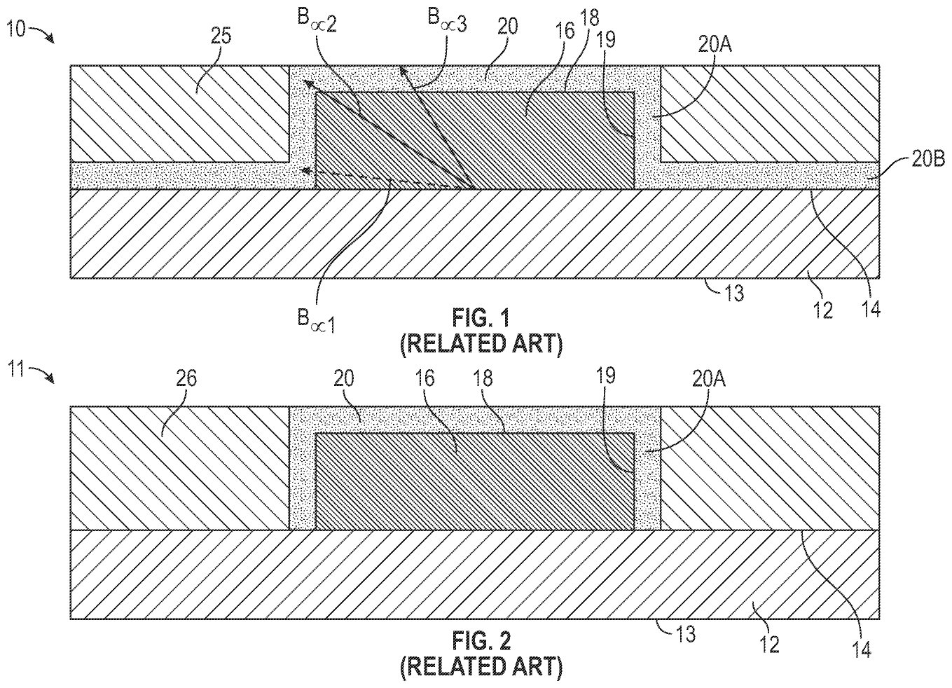

To provide context for embodiments described herein, conventional solid state light emitting devices will be described in conjunction with FIGS. 1 and 2, before embodiments of the present disclosure are described in connection with the remaining figures.

FIG. 1 is a simplified cross-sectional view of a first conventional solid state light emitting device 10 including a LED chip 16 supported by a submount 12, with a first lumiphoric material layer portion 20 contacting a top or outer surface 18 of the LED chip 16, wherein a second lumiphoric layer portion 20A contacts lateral edge surfaces 19 of the LED chip 16, and a third lumiphoric layer portion 20B contacts portions of a first (upper) surface 14 of the submount 12 that extend away from the LED chip 16. During fabrication of the device 10, lumiphoric material may be applied over outer and lateral edge surfaces 18, 19 of the LED chip 16 and over the submount 12 before a reflective material 25 is provided. The submount 12 (which may embody a substrate) includes a second (lower) surface 13 that opposes the first surface 14 contacting the LED chip 16. The reflective material 25 is arranged laterally adjacent to the LED chip 16 in contact with the second lumiphoric layer portion 20A and the third lumiphoric layer portion 20B. While it is to be appreciated that light is generally emitted in all directions from the LED chip 16, three light beams (i.e., B_{α1}, B_{α2}, and B_{α3}) emanating from a center point of the LED chip at low, medium, and high emission angles α1, α2, and α3, respectively, are shown in FIG. 1. A light beam B_{α1} having a low emission angle α1 may be wavelength converted in the third lumiphoric layer portion 20B and trapped between the submount 14 and the third lumiphoric layer portion 20B without exiting the light emitting device 10. A light beam B_{α2} having a medium emission angle α2 may be wavelength converted in the second lumiphoric layer portion 20A and reflected by the reflective material 25 either back to the LED 16 or outward through the first lumiphoric layer portion 20. A light beam B_{α3} having a high emission angle α3 may be wavelength converted in the first lumiphoric layer portion and exit the light emitting device 10, wherein the first lumiphoric layer portion 20 defines a light emitting surface of the device 10.

FIG. 2 is a simplified cross-sectional view of a second conventional solid state light emitting device 11 including a LED chip 16 supported by a submount 12, with a first lumiphoric material layer portion 20 contacting a top or outer surface 18 of the LED chip 16, and with a second lumiphoric layer portion 20A contacting lateral edge surfaces 19 of the LED chip 16. The submount 12 (which may embody a substrate) includes a second (lower) surface 13 that opposes the first surface 14 of the submount 12 in contact with the LED chip 16. A reflective material 25 is arranged laterally adjacent to the LED chip 16 in contact with the second lumiphoric layer portion 20A and the portions of the upper surface. The absence of lumiphoric material between the submount 12 and the reflective material 25 eliminates the trapping of photons between the submount 12 and the reflective material 2 (thereby improving luminous efficacy of the solid state light emitting device 11 relative to the device 10 illustrated in FIG. 1), but presence of the second lumiphoric material portion 20A still results in sub-optimal luminous efficacy.

In a departure from the conventional light emitting devices 10, 11 described in connection with FIGS. 1 and 2, solid state light emitting devices according to various embodiments of the present disclosure include lens structures arranged over base structures or subassemblies that include at least one solid state light emitter, wherein if lumiphoric material is present, such lumiphoric is material deposited over a top surface of a LED chip, with side surfaces of the LED chip contacting reflective material and being devoid of lumiphoric material. This configuration can be achieved utilizing a sealing template for applying lumiphoric material during fabrication of a base structure, prior to application or formation of a lens structure.

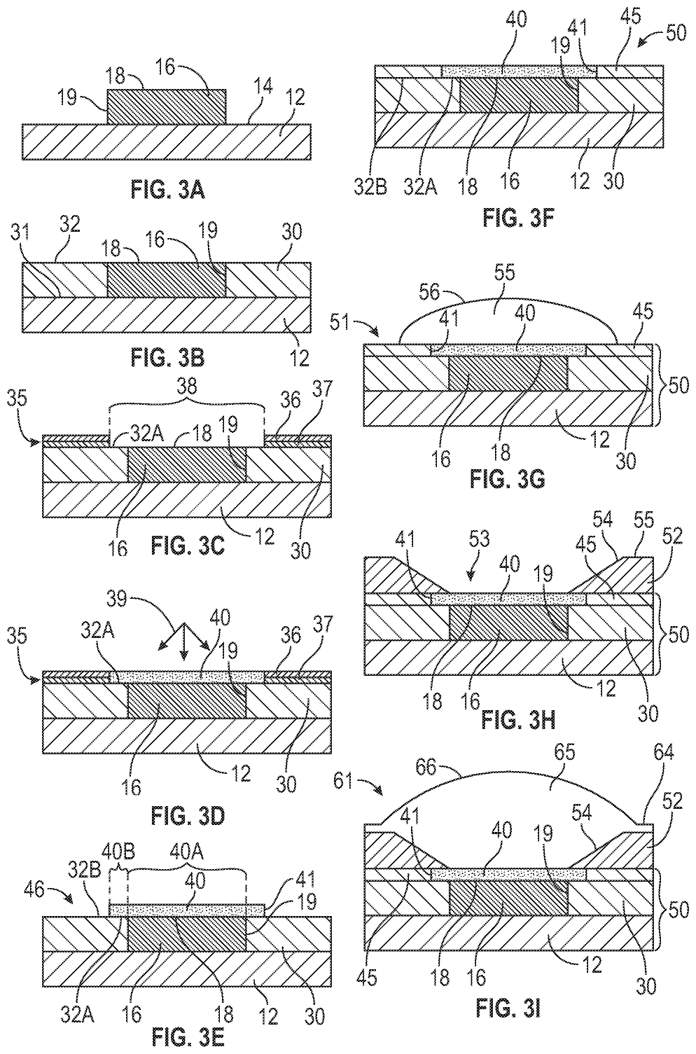

FIGS. 3A-3F are simplified cross-sectional views depicting steps utilizing a sealing template in producing at least a base or subassembly portion of solid state light emitting device according to one embodiment.

FIG. 3A illustrates a LED chip 16 mounted on a first (upper) surface 14 of a submount 12, with the LED chip 16 having a top or outer surface 18 (arranged distal from the first surface 14 of the submount 12) and having lateral edge surfaces 19. In certain embodiments, the LED chip 16 may have a flip-chip configuration, wherein mounting of the LED chip 16 to the first surface 14 of the submount may involve making electrical connections between anode and cathode contacts (not shown) of the LED chip 16 and contact pads (not shown) of the submount 12.

FIG. 3B shows the items of FIG. 3A following addition of a layer of fill material over the submount 12 to contact lateral edge surfaces 19 of the LED chip 16, with the top or outer surface 18 of the LED chip 16 remaining exposed. In certain embodiments, the fill material 30 comprises a reflective material, such as white (e.g., titanium dioxide or TiO₂) particles contained in a silicone binder. The fill material layer 30 may be applied by any suitable method(s), such as jet pumping, screen printing, dispensing, spraying or the like, optionally followed by a skimming step (e.g., using a rubber blade or squeegee) to remove excess thickness of fill material. In certain embodiments, the fill material layer 30 includes a lower boundary 31 contacting the submount 12 and includes an upper boundary 32 arranged at substantially the same height or level as the top surface 18 of the LED chip 16. In certain embodiments, one or more secondary components (e.g., electrostatic discharge diodes) (not shown) having a lower height than the LED chip 16 may also be supported by the submount 12, and may be encapsulated in the fill material layer 30. As shown in FIG. 3B, in certain embodiments, the upper boundary 32 of the fill material 30 may be substantially coplanar with the exposed outer surface 18 of the LED chip 16 to yield a continuous flat surface.

FIG. 3C shows the items of FIG. 3B following addition of a sealing template 35, which includes a carrier layer 36 and an adhesive layer 37, over the fill material layer 30. The sealing template 35 may be applied by pressing using a flat member and/or one or more rollers (not shown). The sealing template 35 defines a window 38 (e.g., a precut window) that is larger than but generally aligned with the LED chip 16, wherein the window 38 also overlaps an LED-adjacent portion 32A of the fill material layer 30. In certain embodiments, the carrier layer 36 comprises a material that is transmissive of UV-spectrum emissions, and the adhesive layer 37 comprises a UV-release adhesive material. The top or outer surface 18 of the LED chip 16 is exposed through the window 38 defined in the sealing template 35.

FIG. 3D shows the items of FIG. 3C following application (using a deposition apparatus 39) of a lumiphoric material layer 40 through the window defined in the template to be deposited on the top or outer surface 18 of the LED chip 16. As shown, the lumiphoric material layer 40 is arranged over the entire outer surface 18 of the LED chip and also overlaps the LED-adjacent top surface portion 32A of the fill material layer 30, so that the lumiphoric material layer 40 is wider than the top or outer surface 18 of the LED chip 16. Providing a lumiphoric material layer 40 that is wider than the top or outer surface 18 of the LED chip 16 ensures that no portions of emissions of the LED chip 16 (including from upper corners thereof) escape without interacting with the lumiphoric material layer 40, thereby enhancing uniformity of color point of resulting emissions over an emissive area of a solid state light-emitting device. In certain embodiments, the lumiphoric material layer 40 comprises lumiphoric material in a silicone binder (e.g., with an exemplary lumiphoric material weight percent of about 66%). Any suitable method may be used to apply the lumiphoric material layer 40, such as spraying, dispensing, jet pumping, and the like. Optionally, any excess thickness of lumiphoric material 40 may be removed by dragging a skimming member (not shown) across the carrier layer 36 of the sealing template 35. Following application of the lumiphoric material 40, such material may be cured and solidified, such as with heat, electromagnetic radiation, and/or other means.

Although only a single lumiphoric material layer 40 is shown, it is to be appreciated that multiple lumiphoric material layers may be applied in sequence, in the same (overlapping) are or different (non-overlapping) areas, including through a single window of a sealing template or through different windows defined in a multi-window sealing template.

After (or during) the curing of the lumiphoric material, UV emissions from an external source (not shown) may be impinged on the sealing template 35 in order to reduce a tack of the adhesive layer 37. Thereafter, the sealing template 35 may be removed from the fill material 30 (e.g., by mechanical pulling). Reduction of tack of the adhesive layer 37 prior to removal of the sealing template 35 beneficially reduced a likelihood of adhesive residue remaining on the underlying fill material 30, and also reduces a likelihood that lumiphoric material 40 will remain adhered laterally to boundaries of the window 38 defined in the sealing template 35, so that portions of lumiphoric material 40 will not be removed when the sealing template 35 is removed from the underlying fill material 30, and a clean lateral edge 41 of the lumiphoric material 40 remains. FIG. 3E shows the items of FIG. 3D following removal of the sealing template 35, wherein the lumiphoric material overlaps the entire top or outer surface 18 of the LED chip 16 as well as LED-adjacent top surface portions 32A of the fill material layer 30, while remaining top surface portions 32B of the fill material layer 30 are exposed. As shown, lateral edge surfaces 19 of the LED chip 16 are fully covered with the fill material 30 and devoid of lumiphoric material, and no lumiphoric material is provided between the fill material 30 and the submount 12.

FIG. 3F shows the items of FIG. 3E, following addition of a second fill material layer 45 to contact lateral edges 41 of the lumiphoric material 40 (which overlaps the outer surface 18 of the LED chip 16 and LED-adjacent top surface portions of the fill material layer 30) to contact the remaining top surface portions 32B of the fill material layer 30, to produce a solid state light-emitting device portion or subassembly 50. In certain embodiments, the second fill material layer 45 comprises reflective material (e.g., titanium dioxide in a silicone binder, with an exemplary titanium dioxide weight percent of about 15%). In certain embodiments, the second material layer 45 comprises a height that is substantially identical to that of the light-altering material layer 40. In certain embodiments, the second fill material layer 45 comprises substantially the same composition as the (first) fill material layer 30. In certain embodiments, the second fill material layer 45 and the fill material layer 30 each comprise reflective material in a binder, wherein the fill material layers 30, 45 may have the same or different reflectivity values. In certain embodiments, second fill material layer 45 comprises a reflective material and/or scattering material in a binder (e.g., silicone) and the fill material layer 30 comprises a reflective material in a binder (e.g., silicone). The second fill material layer may serve to scatter and/or reflect light that escapes through lateral boundaries 41 of the light-altering material layer 40, such that in certain embodiments a desirable beam cutoff pattern and/or improved luminous efficacy may be provided. The solid state light-emitting subassembly 50 is suitable for forming of various solid state light-emitting devices that including lenses contacting the lumiphoric material layer (with or without an optional clear layer therebetween), wherein such lens may be optionally retained in reflector cavities of various sizes and shapes.

With continued reference to FIG. 3F, in certain embodiments, the submount 12 comprises a ceramic material, the LED chip 16 comprises semiconductor materials (e.g., III-nitride materials on a sapphire or silicon carbide substrate), and the remaining layers of the solid state light emitting subassembly 50 (including the fill material layer 30, the lumiphoric material layer 40, and the second fill material layer 45) are substantially matched in coefficient of thermal expansion (CTE) properties, wherein “substantial matching” of CTE properties may embody inter-layer CTE differences of less than 20%, less than 15%, less than 10%, less than 5%, or less than 2% In certain embodiments, fill material layer 30, the lumiphoric material layer 40, and the second fill material layer 45 may comprise the same binder (e.g., silicone), loaded with particles of the same or different composition, and with the same or different concentration. Optionally, in certain embodiments a clear (transparent) layer may be provided over the second fill material layer 45 and the lumiphoric material layer 40.

FIG. 3G shows a solid state light emitting component 51 including the solid state light subassembly 50 of FIG. 3F, following formation of a lens material 55 over an entirety of the lumiphoric material layer 40 and portions of the second fill material layer 45. The lens material 65 has an outwardly curved (convex, partially hemispherical) shape. In certain embodiments, the lens material 55 may be formed by dispensing material (optionally into a cavity of a mold, not shown) over the solid state light-emitting assembly 50 followed by curing, and the lens material 55 comprise silicone (or another material that is substantially CTE matched with the fill material layer 30, the lumiphoric material layer 40, and the second fill material layer 30.

FIG. 3H shows the solid state light-emitting subassembly 50 of FIG. 3F following formation of an elevated reflector structure 52 over the second fill material layer 45. The elevated reflector structure 52 includes an inclined reflector wall 54 that bounds a reflector cavity 53. In certain embodiments, the elevated reflector structure 52 comprises reflective particles (e.g., titanium dioxide) in a silicone binder. In certain embodiments, a portion of the elevated reflector structure 52 may overlap peripheral portions of the light-altering material layer 40, preferably without overlapping the LED chip 16.

FIG. 3I shows a solid state light emitting component 61 including the items of FIG. 3H (i.e., the solid state light-emitting subassembly 50 and elevated reflector structure 52), following addition of a lens material 65 to the reflector cavity 53 to contact the angled reflector wall 54. As shown, the lens material 65 is arranged in contact with the lumiphoric material 40 and the reflector wall 54, and the lens material 65 comprises an outwardly curved (convex) outer surface 66 through which light is extracted from (i.e., exits) the device 51. In certain embodiments, the lens material 65 comprises silicone. In certain embodiments, the lens material 65 is substantially CTE matched to the elevated reflector structure 52, and optionally may be substantially CTE matched to the remaining device layers (i.e., fill material layer 30, lumiphoric material layer 40, and second fill material layer 45), wherein in certain embodiments each of the foregoing items may comprise silicone (whether or not loaded with particulate material).

Although the preceding embodiments herein include fill material laterally bounding a light-altering (e.g., lumiphoric) material layer, the disclosure is not so limited. In certain embodiments, a solid state light-emitting component includes a light-altering material that is not laterally bounded by fill material contacting lateral edges of the light-altering material.

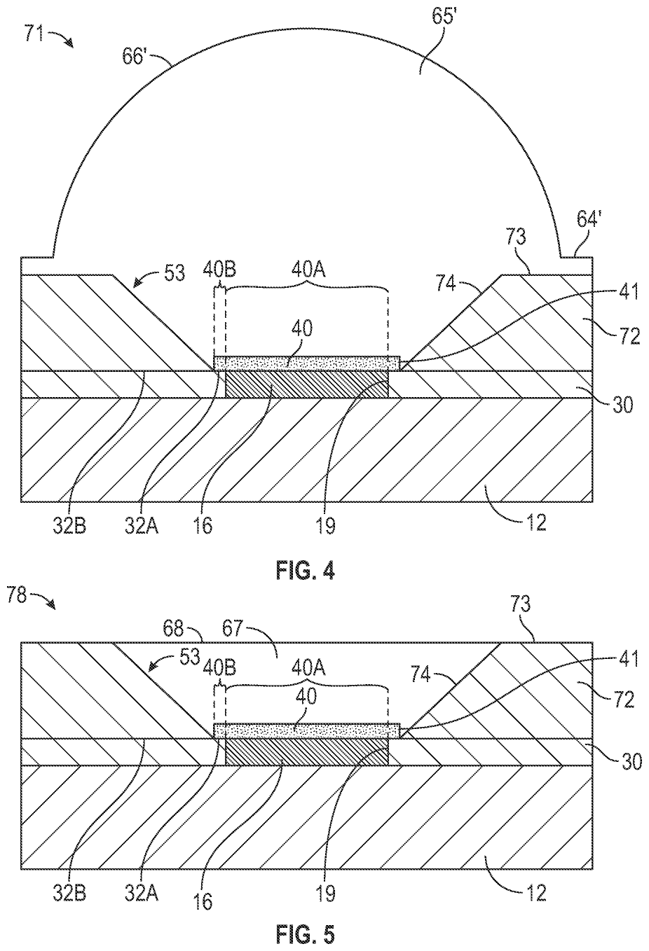

FIG. 4 illustrates a solid state light emitting component 71 according to one embodiment, including a hemispherical lens structure 65 arranged over a LED chip 16 and lumiphoric material layer 40, and suitable for producing focusing light output emissions. The LED chip 16 is supported by a substrate 12, with a first fill material 30 contacting lateral boundaries 19 of the LED chip 16. A lumiphoric material layer 40 includes a central portion 40A provided in contact with an entire upper surface of the LED chip 16, and includes peripheral portions 40B arranged in contact with LED-adjacent top surface portions 32A of the fill material layer 30, while remaining top surface portions 32B of the fill material layer 30 are covered by an elevated reflector structure 72. The elevated reflector structure 72 defines an inclined reflector wall 74 that bounds a reflector cavity 53 containing part of the lens material 65′, and further defines an upper surface 73. In certain embodiments, the inclined reflector wall 74 is inclined from horizontal at an angle in a range of from about 40 to 44 degrees, or about 42 degrees. A center portion of the lens material 65′ has an outwardly curved (convex and substantially hemispherical) surface 66′, with the lens material 65′ further including flat extension portions 64′ that overlap the upper surface 73 of the reflector structure 72. In certain embodiments, the lens material 65′ may be formed by molding over the reflector structure 72 and the lumiphoric material layer 40, and may comprise silicone (or another material that is substantially CTE matched with the first fill material layer 30, the lumiphoric material layer 40, and the reflector structure 72, wherein the foregoing items may also comprise silicone with particulate material bound therein). As shown, lateral edges 41 of the lumiphoric material layer 40 may be uncovered, or alternatively may be covered with portions of the reflector structure 72.

FIG. 5 illustrates a solid state light emitting component 78 that is similar to that shown in FIG. 4, but including a lens material 67 fully contained withing a cavity 53 of the elevated reflector structure 52 and having a flat outer (i.e., light exiting) surface 68 registered with an upper surface 73 of the reflector structure 52, with the upper surface 73 being uncovered. The remaining items of FIG. 5 are identical to those described in connection with FIG. 4, such that the descriptions of the remaining elements in FIG. 4 are incorporated by reference with respect to FIG. 5 and not repeated again. As compared with the device 71 shown in FIG. 4, the solid state lighting component 78 of FIG. 5 is suitable for producing dispersed light output emissions having a larger viewing angle.

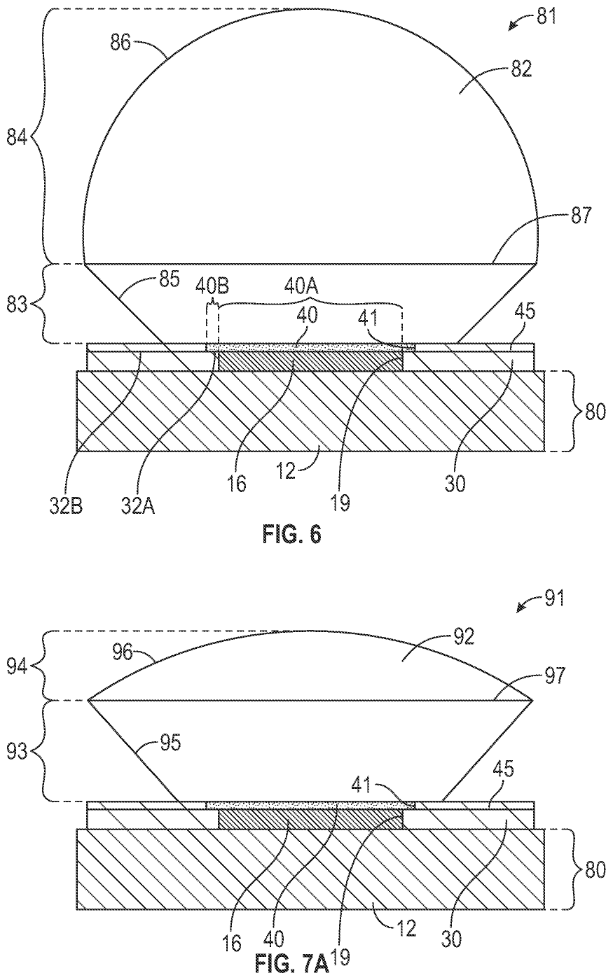

FIG. 6 illustrates a solid state light emitting component 81 according to one embodiment, including a unitary lens structure 82 arranged over a base structure or subassembly 80. The base structure or subassembly 80 includes a LED chip 16 supported by a substrate 12, with a first fill material 30 contacting lateral boundaries 19 of the LED chip 16. A lumiphoric material layer 40 includes a central portion 40A provided in contact with an entire upper surface of the LED chip 16, and includes peripheral portions 40B arranged in contact with LED-adjacent top surface portions 32A of the fill material layer 30. A second fill material 45 is arranged over remaining portions 32B of the first fill material 30, and in contact with lateral boundaries 41 of the lumiphoric material layer 40. The lumiphoric material layer 40 in combination with the second fill material layer 45 provide a flat upper surface for receiving the unitary lens structure 82. The unitary lens structure 82 includes a first portion 83 and a second portion 84 joined at a transition 87. In certain embodiments, the first portion 83 and the second portion 84 of the lens structure 82 are integrally formed (e.g., by molding, cleaving, cutting, machining, etc.). In certain embodiments, the first portion 83 and a second portion 84 are adhered or otherwise affixed to one another at the transition 87. In certain embodiments, the first portion 83 and the second portion 84 comprise substantially the same index of refraction, and may be formed of the same material (e.g., silicone or the like). The first portion 83 of the lens structure 82 has a width that increases with distance away from the LED chip 16, and is arranged in contact with the lumiphoric material layer 40 as well as portion of the second fill material layer 45. The first portion 83 of the lens structure is bounded by peripheral wall surfaces 85 configured to produce total internal reflection (TIR) of emissions generated by an emissive center of a solid state emitter (encompassing the LED chip 16 and the lumiphoric material layer 40). In certain embodiments, the first portion 83 of the lens structure 82 comprises a frustoconical shape (i.e., having a round top view profile), but other shapes are possible such as a truncated pyramidal shape (i.e., having a square top view profile). The second portion 84 of the lens structure 82 includes an outer light extraction (or light exit) surface 86 having a substantially hemispherical shape. During operation of the light emitting component 81, emissions generated by the LED chip 16 are impinged on the lumiphoric material layer 40 (with such emissions being reflected by the fill material layers 30, 45) and emitted into the first portion 83 of the lens structure 82. Any emissions emanating from an emissive center of the LED chip 16 and the lumiphoric material layer 40 (in combination embodying a solid state light emitter) and incident on the peripheral wall surfaces 85 is reflected in a generally upward direction toward the second portion 84 of the lens structure 82, and exit through the hemispherical outer surface 86 to a surrounding environment.

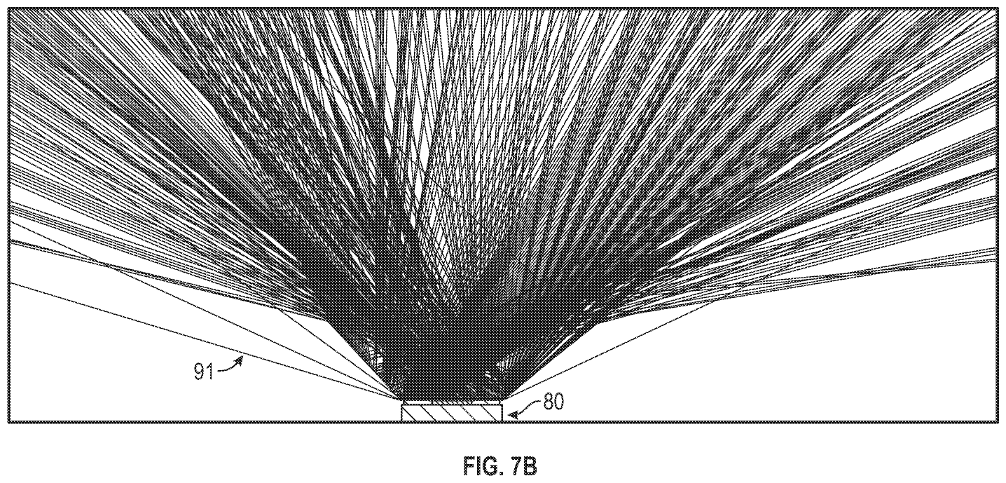

FIG. 7A illustrates a solid state light emitting component 91 according to one embodiment similar to that shown in FIG. 6, but with a second (upper) portion 94 of the unitary lens structure 92 having a (flattened) partially spherical shape. All constituents of the base structure or subassembly 80 of FIG. 7A is identical to the same items described in connection with FIG. 6, are incorporated by reference and will not be described again. The unitary lens structure 92 includes a first portion 93 and a second portion 94 joined at a transition 97. In certain embodiments, the first portion 93 and the second portion 94 of the lens structure 92 are integrally formed (e.g., by molding, cleaving, cutting, machining, etc.), or are adhered or otherwise affixed to one another at the transition 97. The first portion 93 of the lens structure 92 has a width that increases with distance away from the LED chip 16, and is arranged in contact with the lumiphoric material layer 40 as well as portion of the second fill material layer 45. The first portion 93 of the lens structure is bounded by peripheral wall surfaces 95 configured to produce TIR of emissions generated by an emissive center of a solid state emitter (encompassing the LED chip 16 and the lumiphoric material layer 40). In certain embodiments, the first portion 93 of the lens structure 92 comprises a frustoconical shape, but other shapes are possible such as a truncated pyramidal shape. The second portion 94 of the lens structure 92 includes an outer light extraction (or light exit) surface 96 having a flattened, partially hemispherical shape. During operation of the light emitting component 91, emissions generated by the LED chip 16 are impinged on the lumiphoric material layer 40 (with such emissions being reflected by the fill material layers 30, 45) and emitted into the first portion 93 of the lens structure 92. Any emissions emanating from an emissive center of the LED chip 16 and the lumiphoric material layer 40 (in combination embodying a solid state light emitter) and incident on the peripheral wall surfaces 95 is reflected in a generally upward direction toward the second portion 94 of the lens structure 92, and exit through the hemispherical outer surface 96 to a surrounding environment.

FIG. 7B is a modeled ray trace diagram showing a pattern of light beams produced by a solid state light emitting component 91 according to the design of FIG. 7A.

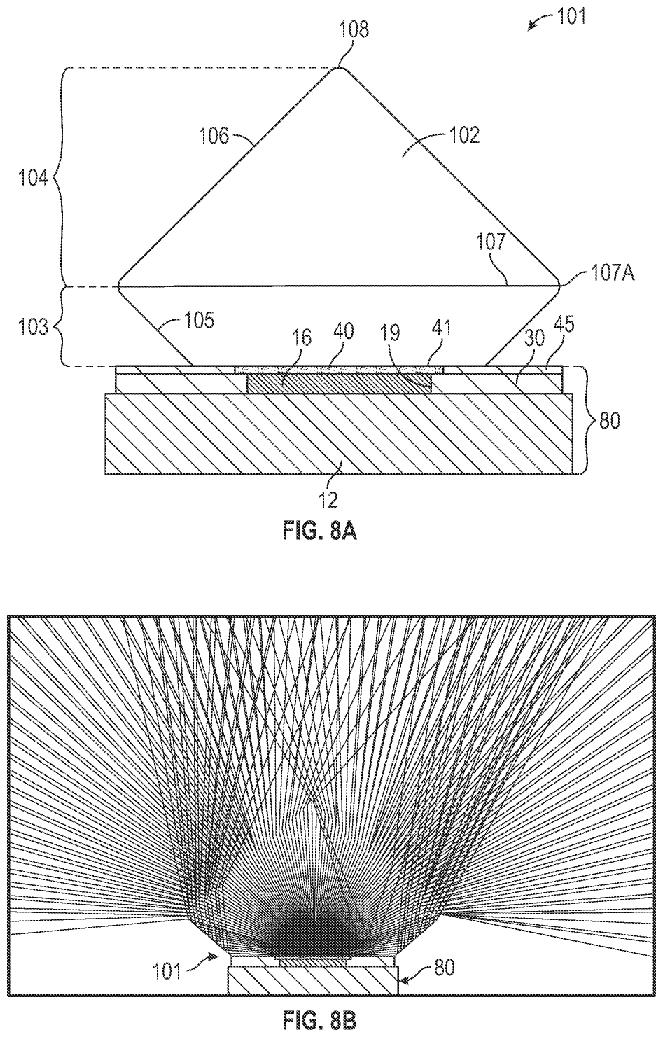

FIG. 8A illustrates a solid state light emitting component 101 including the same base structure or subassembly 80 introduced in FIG. 6, wherein prior descriptions of all components of the base structure or subassembly 80 are incorporated by reference with respect to FIG. 8A, and will not be repeated. A unitary lens structure 102 is provided over the lumiphoric material layer 40 and portions of the second fill material layer 45, and includes a first portion 103 and a second portion 104 joined at a transition 107. In certain embodiments, the first portion 103 and the second portion 104 of the lens structure 102 are integrally formed (e.g., by molding, cleaving, cutting, machining, etc.), or are adhered or otherwise affixed to one another at the transition 107. In certain embodiments, the transition 107 has a small radius curved profile 107A. The first portion 103 of the lens structure 102 has a width that increases with distance away from the LED chip 16, and is arranged in contact with the lumiphoric material layer 40 as well as portion of the second fill material layer 45. The first portion 103 of the lens structure is bounded by peripheral wall surfaces 105 configured to produce TIR of emissions generated by an emissive center of a solid state emitter (encompassing the LED chip 16 and the lumiphoric material layer 40). The second portion 104 of the lens structure 102 includes an inclined outer light extraction (or light exit) surface 106 terminated at a small radius terminal end 108. In certain embodiments, the first and second portions 103, 104 of the lens structure 102 may comprise shapes independently selected from frustoconical (having a round top view profile), truncated pyramidal (having a square or rectangular top view profile), or other shapes (including shapes having oval, other rounded, or trapezoidal top view profiles. During operation of the light emitting component 101, emissions generated by the LED chip 16 are impinged on the lumiphoric material layer 40 (with such emissions being reflected by the fill material layers 30, 45) and emitted into the first portion 103 of the lens structure 102. Any emissions emanating from an emissive center of the LED chip 16 and the lumiphoric material layer 40 (in combination embodying a solid state light emitter) and incident on the peripheral wall surfaces 105 is reflected in a generally upward direction toward the second portion 104 of the lens structure 102, and exit through the inclined outer light extraction surfaces 106 to a surrounding environment.

FIG. 8B is a modeled ray trace diagram showing a pattern of light beams produced by a solid state light emitting device 101 according to the design of FIG. 8A.

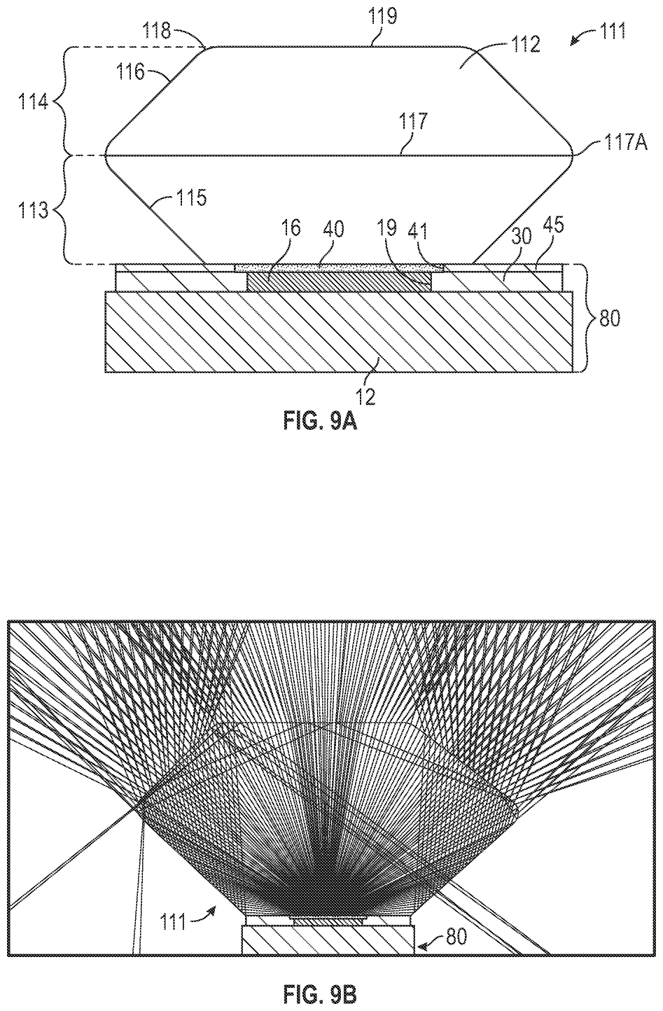

FIG. 9A illustrates a solid state light emitting component 111 according to one embodiment similar to that shown in FIG. 8A, but including a second (upper) portion 114 of a lens structure having a truncated tapered (e.g., conical or pyramidal) shape with a central surface 119 that may be substantially parallel to a submount 12. The solid state light emitting component 111 includes the same base structure or subassembly 80 introduced in FIG. 6, wherein prior descriptions of all components of the base structure or subassembly 80 are incorporated by reference with respect to FIG. 9A, and will not be repeated. A unitary lens structure 112 is provided over the lumiphoric material layer 40 and portions of the second fill material layer 45, and includes a first portion 113 and a second portion 114 joined at a transition 117. In certain embodiments, the first portion 113 and the second portion 114 of the lens structure 112 are integrally formed (e.g., by molding, cleaving, cutting, machining, etc.), or are adhered or otherwise affixed to one another at the transition 117. In certain embodiments, the transition 117 has a small radius curved profile 117A. The first portion 113 of the lens structure 112 has a width that increases with distance away from the LED chip 16, and is arranged in contact with the lumiphoric material layer 40 as well as portion of the second fill material layer 45. The first portion 113 of the lens structure is bounded by peripheral wall surfaces 115 configured to produce TIR of emissions generated by an emissive center of a solid state emitter (encompassing the LED chip 16 and the lumiphoric material layer 40). The second portion 114 of the lens structure 112 includes an inclined outer light extraction (or light exit) surface 116 that transitions (at curved interface 118) to a central surface 119. In certain embodiments, the first and second portions 113, 114 of the lens structure 112 may comprise shapes independently selected from frustoconical, truncated pyramidal, or other shapes. During operation of the light emitting component 111, emissions generated by the LED chip 16 are impinged on the lumiphoric material layer 40 (with such emissions being reflected by the fill material layers 30, 45) and emitted into the first portion 113 of the lens structure 112. Any emissions emanating from an emissive center of the LED chip 16 and the lumiphoric material layer 40 (in combination embodying a solid state light emitter) and incident on the peripheral wall surfaces 115 is reflected in a generally upward direction toward the second portion 114 of the lens structure 112, and exit through the inclined outer light extraction surfaces 116 and the central surface 119 to a surrounding environment.

FIG. 9B is a modeled ray trace diagram showing a pattern of light beams produced by a solid state light emitting device 11 similar to the design of FIG. 9A.

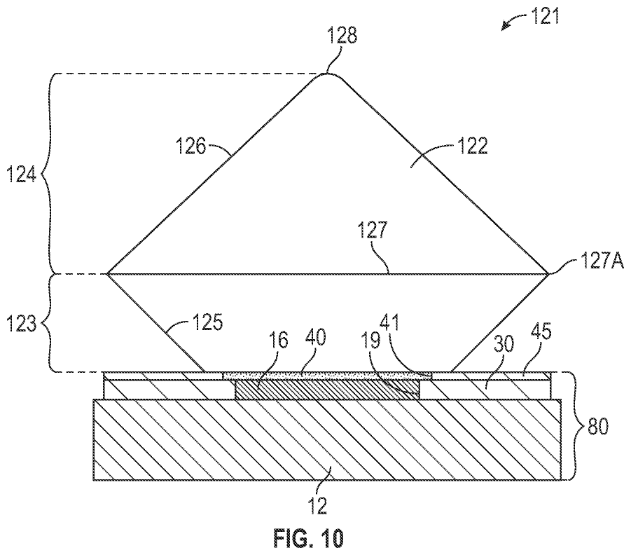

FIG. 10 illustrates a solid state light emitting component 121 according to one embodiment similar to that shown in FIG. 8A, but including a sharp boundary between a first (lower) portion 123 and a second (upper) portion 124 of a unitary lens structure 122. The solid state light emitting component 121 includes the same base structure or subassembly 80 introduced in FIG. 6, wherein prior descriptions of all components of the base structure or subassembly 80 are incorporated by reference with respect to FIG. 9A. A unitary lens structure 122 is provided over the lumiphoric material layer 40 and portions of the second fill material layer 45, and includes a first portion 123 and a second portion 124 joined at a transition 127 having a sharp angular profile 127A. In certain embodiments, the first portion 123 and the second portion 124 of the lens structure 122 are integrally formed (e.g., by molding, cleaving, cutting, machining, etc.), or are adhered or otherwise affixed to one another at the transition 127. The first portion 123 of the lens structure 122 has a width that increases with distance away from the LED chip 16, and is arranged in contact with the lumiphoric material layer 40 as well as portion of the second fill material layer 45. The first portion 123 of the lens structure is bounded by peripheral wall surfaces 125 configured to produce TIR of emissions generated by an emissive center of a solid state emitter encompassing the LED chip 16 and the lumiphoric material layer 40. The second portion 124 of the lens structure 122 includes an inclined outer light extraction (or light exit) surface 126. In certain embodiments, the first and second portions 123, 124 of the lens structure 122 may comprise shapes independently selected from frustoconical, truncated pyramidal, or other shapes. During operation of the light emitting component 121, emissions generated by the LED chip 16 are impinged on the lumiphoric material layer 40 (with such emissions being reflected by the fill material layers 30, 45) and emitted into the first portion 123 of the lens structure 122. Any emissions emanating from an emissive center of the LED chip 16 and the lumiphoric material layer 40, and incident on the peripheral wall surfaces 125, is reflected in a generally upward direction toward the second portion 124 of the lens structure 122, and exit through the inclined outer light extraction surfaces 126 to a surrounding environment.

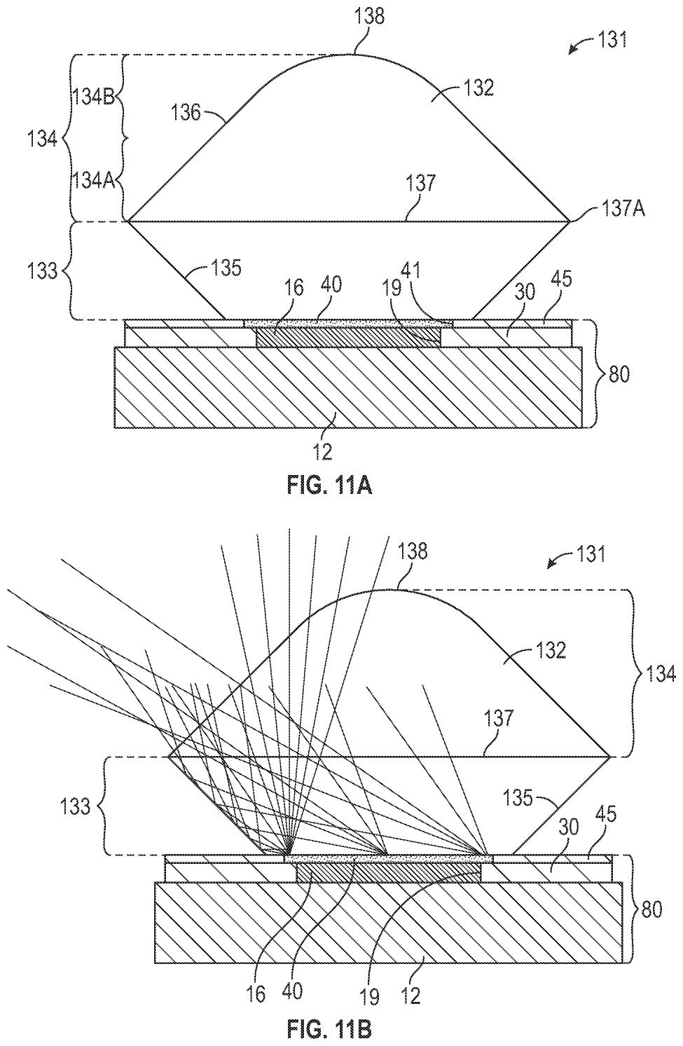

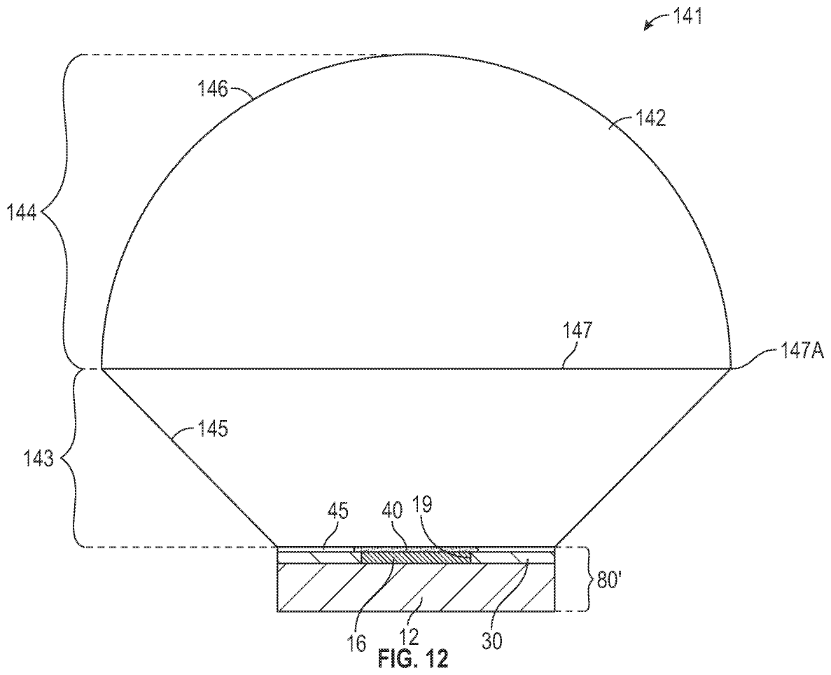

FIG. 11A illustrates a solid state light emitting component 131 according to one embodiment similar to prior embodiments, but including a unitary lens structure 132 having a truncated pyramidal first (lower) portion 133 and having a second (upper) portion 134 that transitions from a truncated pyramidal shape in a proximal segment 134A thereof to a domed shape in a distal segment 134B thereof. Restated, the unitary lens structure 132 has a profile when viewed from above that appears square for the first portion 133 having a truncated pyramidal shape, and that appears round (or nearly round) for the second portion 134 that has a domed shape, with a transition from square top view profile to rounded top view profile therebetween The solid state light emitting component 131 includes the same base structure or subassembly 80 introduced in FIG. 6, wherein prior descriptions of all components of the base structure or subassembly 80 are incorporated by reference with respect to FIG. 11A. A unitary lens structure 132 is provided over the lumiphoric material layer 40 and portions of the second fill material layer 45, and includes a first portion 133 and a second portion 134 joined at a transition 137, which may have a sharp angular transition profile 137A. In certain embodiments, the first portion 133 and the second portion 134 of the lens structure 132 are integrally formed (e.g., by molding, cleaving, cutting, machining, etc.), or are adhered or otherwise affixed to one another at the transition 137. The first portion 133 of the lens structure 132 has a width that increases with distance away from the LED chip 16 (as part of an inverted truncated pyramidal shape), and is arranged in contact with the lumiphoric material layer 40 as well as portion of the second fill material layer 45. The first portion 133 of the lens structure is bounded by peripheral wall surfaces 135 configured to produce TIR of emissions generated by an emissive center of a solid state emitter encompassing the LED chip 16 and the lumiphoric material layer 40. The second portion 134 of the lens structure 132 includes an inclined outer light extraction (or light exit) surface 136 that transitions to a domed surface 138. During operation of the light emitting component 131, emissions generated by the LED chip 16 are impinged on the lumiphoric material layer 40 (with such emissions being reflected by the fill material layers 30, 45) and emitted into the first portion 133 of the lens structure 132. Any emissions emanating from an emissive center of the LED chip 16 and the lumiphoric material layer 40 (in combination embodying a solid state light emitter) and incident on the peripheral wall surfaces 135 is reflected in a generally upward direction toward the second portion 134 of the lens structure 132, and exit through the inclined outer light extraction surfaces 136 and the domed surface 138 to a surrounding environment.

FIG. 11B shows the solid state light emitting component 131 of FIG. 11A having superimposed thereon a partial ray trace diagram showing light beams emanating from three positions along an upper surface of the LED chip 16 and exiting from the inclined surfaces 136 and domed surface 138 of the second portion 134 of the lens structure 132.

In certain embodiments, a unitary lens structure may have lateral dimensions (e.g., width) that exceed a width of a submount and a corresponding base structure or subassembly. FIG. 12 illustrates a solid state light emitting component 141 according to one embodiment, including a unitary lens structure 141 having a width that significantly exceeds a width of a base structure or subassembly 80″ as well as a submount 12 thereof. The extended length of the TIR structure allows for more light to be directed by TIR; thus, tighter viewing angles can be attained. The base structure or subassembly 80′ includes a LED chip 16 supported by a submount 12, with a first fill material 30 contacting lateral side surfaces of the LED chip 16 as well as a surface of the submount, wherein a lumiphoric material layer 40 is arranged over the LED chip 16 and portions of the first fill material 30, and a second fill material layer is arranged over portions of the first fill material and in contact with lateral boundaries of the lumiphoric material layer 40. A unitary lens structure 142 is provided over the lumiphoric material layer 40 and portions of the second fill material layer 45, and includes a first portion 143 and a second portion 144 joined at a transition 147, which may have a sharp angular transition profile 147A. In certain embodiments, the first portion 143 and the second portion 144 of the lens structure 142 are integrally formed (e.g., by molding, cleaving, cutting, machining, etc.), or are adhered or otherwise affixed to one another at the transition 147. The first portion 143 of the lens structure 142 has a width that increases with distance away from the LED chip 16 and may embody any suitable shape (e.g., frustoconical, truncated pyramidal, or the like), with the first portion 143 of the lens structure 142 is arranged in contact with the lumiphoric material layer 40 as well as portion of the second fill material layer 45. The first portion 143 of the lens structure is bounded by peripheral wall surfaces 145 configured to produce TIR of emissions generated by an emissive center of a solid state emitter encompassing the LED chip 16 and the lumiphoric material layer 40. The second portion 144 of the lens structure 142 has a convex shape with a hemispherical light extraction surface 146. During operation of the light emitting component 141, emissions generated by the LED chip 16 are impinged on the lumiphoric material layer 40 (with such emissions being reflected by the fill material layers 30, 45) and emitted into the first portion 143 of the lens structure 142. Any emissions emanating from an emissive center of the LED chip 16 and the lumiphoric material layer 40 (in combination embodying a solid state light emitter) and incident on the peripheral wall surfaces 145 is reflected in a generally upward direction toward the second portion 144 of the lens structure 142, and exit through the hemispherical light extraction surface 136 to a surrounding environment.

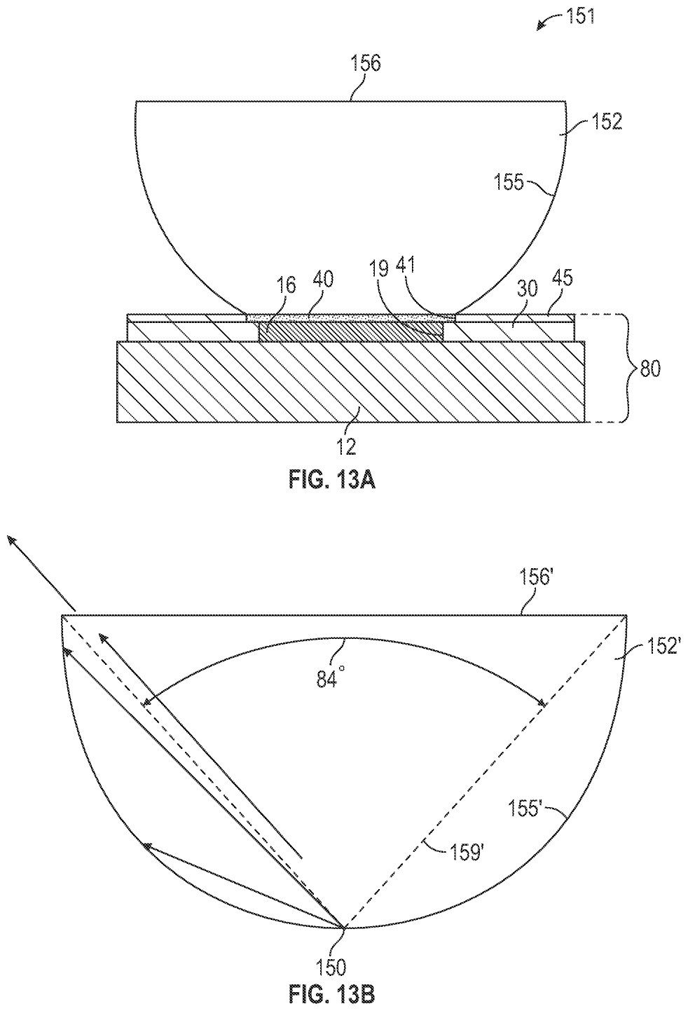

In certain embodiments, a unitary lens structure may incorporate one or more curved surfaces configured to produce TIR in order to shape output emissions of a solid state lighting device. FIG. 13A illustrates a solid state light emitting component 151 according to one embodiment, including a unitary lens structure 152 arranged over a base portion or subassembly 80, the lens structure 152 having a curved surface 155 arranged along a lateral boundary thereof and configured to produce TIR of emissions emanating from an emissive center of a solid state emitter that includes a LED chip 16 and lumiphoric material layer 40 of the base portion 80. The solid state light emitting component 151 includes the same base structure or subassembly 80 introduced in FIG. 6, wherein prior descriptions of all components of the base structure or subassembly 80 are incorporated by reference with respect to FIG. 13A. The lens structure 152 has a width that increases with distance away from the LED chip 16, and terminates at a flat light extraction surface 156 that may be parallel with major surfaces of the submount 12. During operation of the light emitting component 151, emissions generated by the LED chip 16 are impinged on the lumiphoric material layer 40 (with such emissions being reflected by the fill material layers 30, 45) and emitted into the lens structure 112. Any emissions emanating from an emissive center of the LED chip 16 and the lumiphoric material layer 40, and incident on the curved peripheral wall surfaces 155, is reflected in a generally upward direction toward the flat light extraction surface 156, through which light exits to a surrounding environment.

FIG. 13B is a partial ray trace diagram for an idealized unitary lens 152′ similar to the unitary lens 152 of the solid state light emitting component of FIG. 13A, but including a continuous curved (instead of truncated curved) lower portion. A simulated emissive center 150 of a solid state light emitter is superimposed on a lower portion of the idealized unitary lens 152′, with dashed sight lines 159′ positioned 84 degrees apart, corresponding to a direct emission cone with a half-angle of 42 degrees. All emissions of the solid state light emitter within this direct emission cone will be transmitted directly (without reflection) through the flat light extraction surface 156′, whereas emissions outside this cone will be reflected by the curved peripheral wall surfaces 155 in a direction toward the flat light extraction surface 156′.

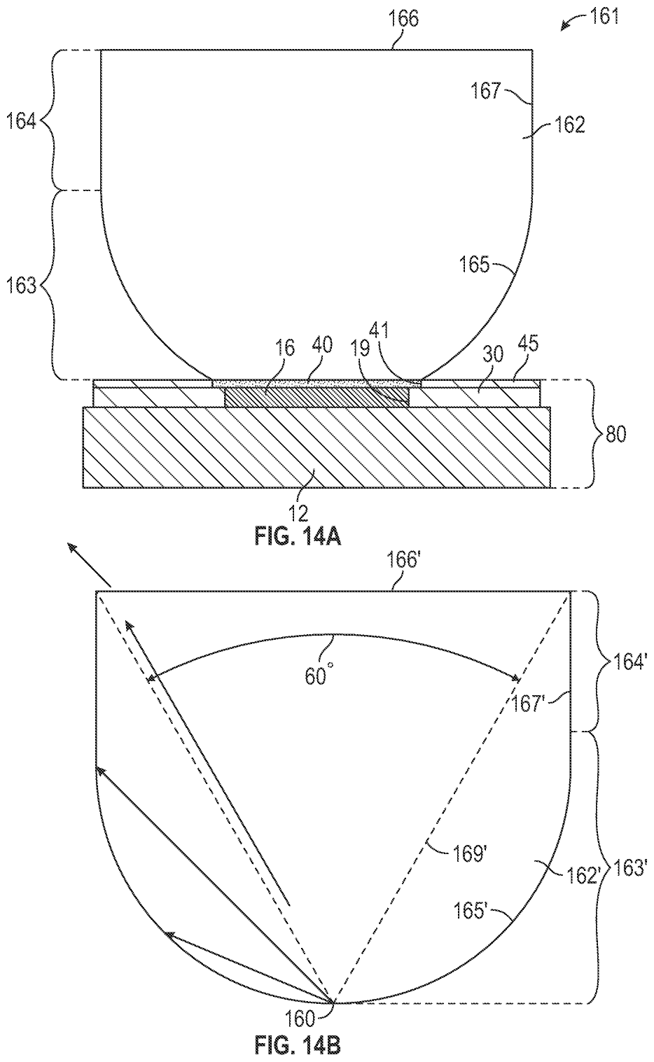

FIG. 14A is a simplified cross-sectional view of a solid state light emitting component 161 according to an embodiment similar to that shown in FIG. 13A, including a unitary lens structure 162 with a first portion 163 having a curved surface 165 arranged along a lateral boundary thereof and configured to produce TIR of emissions, and further including a second portion 164 of the unitary lens structure 162 having a constant width and arranged distal from the LED chip 16, thereby providing a narrower direct emission cone. The solid state light emitting component 161 includes the same base structure or subassembly 80 introduced in FIG. 6, wherein prior descriptions of all components of the base structure or subassembly 80 are incorporated by reference with respect to FIG. 14A. The second portion 164 of the lens structure has a lateral wall 167 substantially perpendicular to a major surface of the submount 12, and terminates at a flat light extraction surface 166 that may be substantially parallel with major surfaces of the submount 12. During operation of the light emitting component 161, emissions generated by the LED chip 16 are impinged on the lumiphoric material layer 40 (with such emissions being reflected by the fill material layers 30, 45) and emitted into the lens structure 162. Any emissions emanating from an emissive center of the LED chip 16 and the lumiphoric material layer 40, and incident on the curved peripheral wall surfaces 165, is reflected in a generally upward direction toward the second lens portion 164 and the flat light extraction surface 166, through which light exits to a surrounding environment.

FIG. 14B is a partial ray trace diagram for an idealized unitary lens 162′ similar to the unitary lens 162 of the solid state light emitting component of FIG. 14A, but including a continuous curved (instead of truncated curved) lower portion. A simulated emissive center 160 of a solid state light emitter is superimposed on a lower portion of the idealized unitary lens 162′, with dashed sight lines 169′ positioned 84 degrees apart, corresponding to a direct emission cone with a half-angle of 42 degrees. All emissions of the solid state light emitter within this direct emission cone will be transmitted directly (without reflection) through the flat light extraction surface 166′, whereas emissions outside this cone will be reflected by the curved peripheral wall surfaces 165′ and/or the flat light extraction surface 166′ in a direction toward the flat light extraction surface 166′.

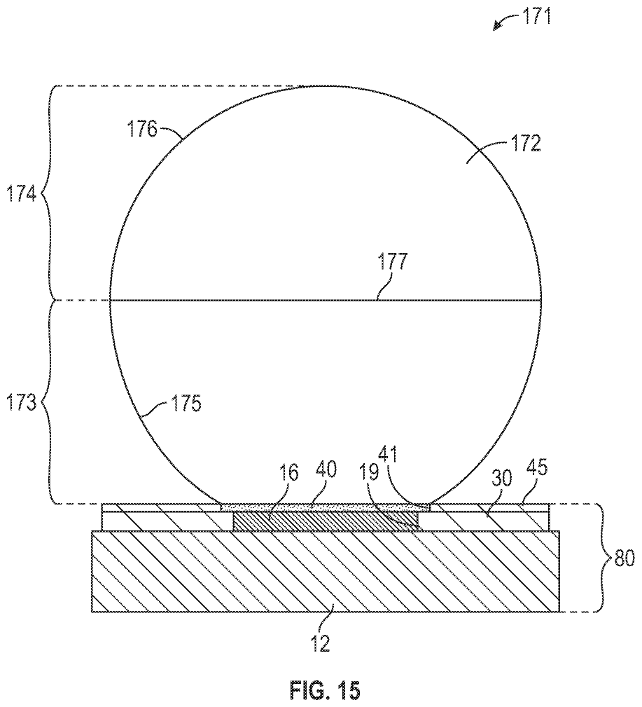

FIG. 15 illustrates a solid state light emitting component 171 according to one embodiment similar to prior embodiments, but including a unitary lens structure 172 having a first (lower) portion 173 with a truncated hemispherical shape and having a second (upper) portion 174 with a hemispherical shape, with the first and second portions 173, 174 joined (e.g., by a clear adhesive or other means) at a transition 177. The solid state light emitting component 171 includes the same base structure or subassembly 80 introduced in FIG. 6, wherein prior descriptions of all components of the base structure or subassembly 80 are incorporated by reference with respect to FIG. 15. The first portion 173 of the lens structure 172 has a curved surface 175 arranged along a lateral boundary thereof and configured to produce TIR of emissions emanating from an emissive center of a solid state emitter that includes the LED chip 16 and lumiphoric material layer 40 of the base portion 80. During operation of the light emitting component 171, emissions generated by the LED chip 16 are impinged on the lumiphoric material layer 40 (with such emissions being reflected by the fill material layers 30, 45) and emitted into the lens structure 172. Any emissions emanating from an emissive center of the LED chip 16 and the lumiphoric material layer 40, and incident on the curved peripheral wall surfaces 175, is reflected in a generally upward direction toward the second lens portion 174 and a curved light extraction surface 176 thereof, through which light exits to a surrounding environment.

As noted previously herein, solid state light emitting components according to various embodiments may include unitary lenses defining one or more recesses therein.

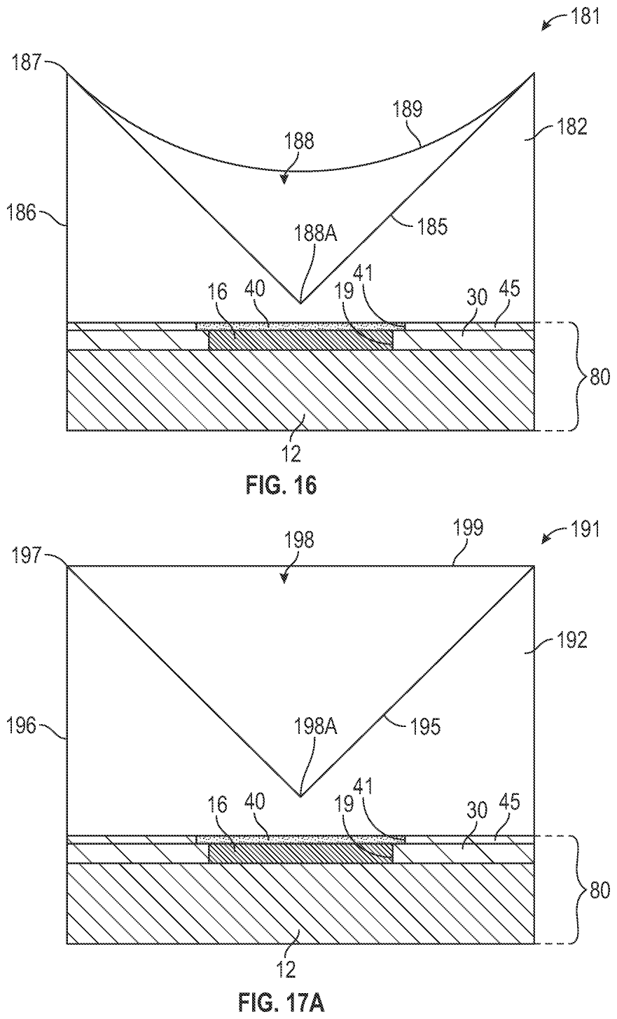

FIG. 16 illustrates a solid state light emitting device according to one embodiment, including a unitary lens structure 182 having a recess 188 defined therein, with the recess 188 having at least one sloped wall 185 tapering to a nadir 188A proximate to the lumiphoric material 41 and LED chip 16. In certain embodiments, the recess 188 has a conical shape and is defined in a lens structure 182 having a square (or other rectangular) top profile, yielding curved upper peripheral edges 189 along an upper boundary of the lens structure 182, with light exit surfaces 186 arranged along lateral edges of the lens structure 182. The sloped wall 185 is configured to produce TIR of emissions emanating from an emissive center of a solid state emitter that includes the LED chip 16 and lumiphoric material layer 40 of the base portion 80, and to reflect light laterally to the light exit surfaces 186 arranged along lateral edges of the lens structure 182. The solid state light emitting component 181 includes the same base structure or subassembly 80 introduced in FIG. 6, wherein prior descriptions of all components of the base structure or subassembly 80 are incorporated by reference with respect to FIG. 16. During operation of the light emitting component 181, emissions generated by the LED chip 16 are impinged on the lumiphoric material layer 40 (with such emissions being reflected by the fill material layers 30, 45) and emitted into the lens structure 182. At least a portion of emissions emanating from an emissive center of the LED chip 16 and the lumiphoric material layer 40 is reflected in a generally upward direction toward the sloped wall 185 bounding the recess 188 and reflected outward toward the light exit surfaces 186, through which light exits to a surrounding environment.

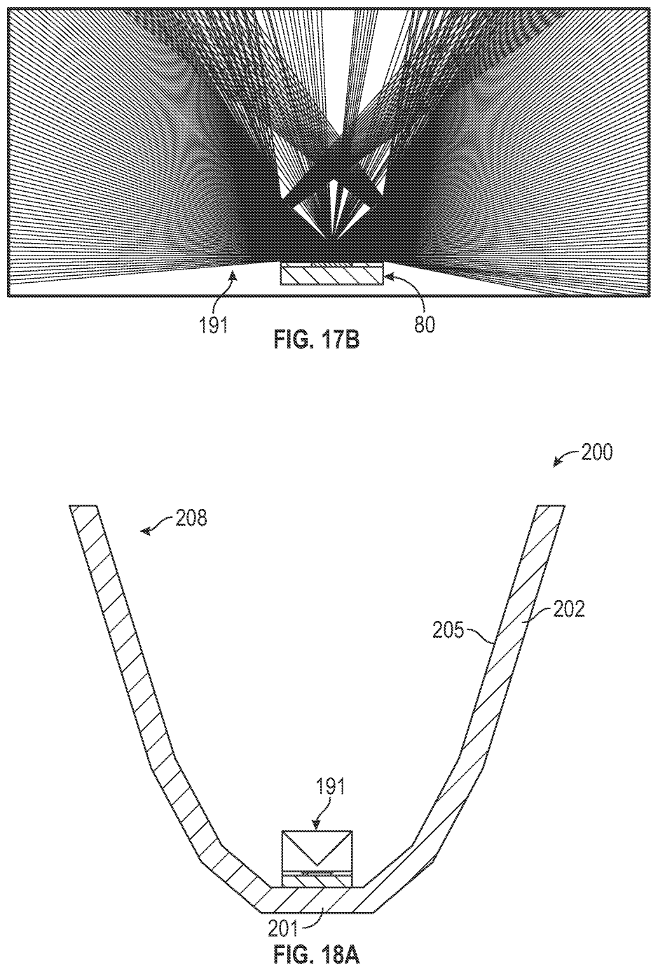

FIG. 17A illustrates a solid state light emitting device according to one embodiment similar to FIG. 16, including a unitary lens structure 192 defining a recess that is bounded by a straight (instead of curved) upper edge 199 thereof. The recess 198 has at least one sloped wall 195 tapering to a nadir 198A proximate to the lumiphoric material 41 and LED chip 16. In certain embodiments, the recess 198 has a conical shape and is defined in a lens structure 192 having a round top profile. In certain embodiments, the recess 198 has an inverted pyramidal shape and is defined in a lens structure 192 having a square top profile. Other recess and lens shapes may be selected. The sloped wall 195 is configured to produce TIR of emissions emanating from an emissive center of a solid state emitter that includes the LED chip 16 and lumiphoric material layer 40 of the base portion 80, and to reflect light laterally to light exit surfaces 196 arranged along lateral edges of the lens structure 192. The solid state light emitting component 191 includes the same base structure or subassembly 80 introduced in FIG. 6, wherein prior descriptions of all components of the base structure or subassembly 80 are incorporated by reference with respect to FIG. 17A. During operation of the light emitting component 191, emissions generated by the LED chip 16 are impinged on the lumiphoric material layer 40 (with such emissions being reflected by the fill material layers 30, 45) and emitted into the lens structure 192. At least a portion of emissions emanating from an emissive center of the LED chip 16 and the lumiphoric material layer 40, and incident on the at least one sloped wall surface 195 bounding the recess 198, is reflected outward toward the light exit surfaces 196, through which light exits to a surrounding environment.

FIG. 17B is a modeled ray trace diagram showing a pattern of light beams produced by the solid state light emitting device 191 of FIG. 17A when positioned in an upward direction. As shown, a majority of emissions of the solid state light emitting device 191 is cast in a lateral direction, with only a small portion of emissions being directed upward through recess.

In certain embodiments, a solid state light emitting component as disclosed herein may be used in conjunction with a secondary reflector structure in order to provide desired light shaping and/or light directing utility.

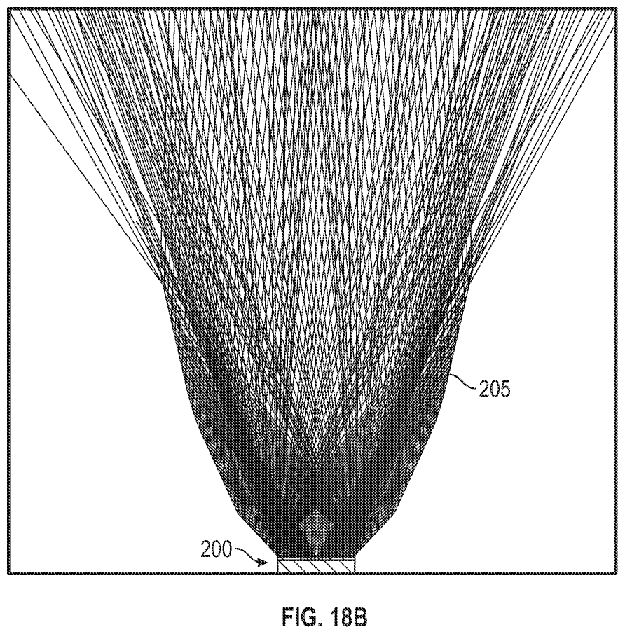

FIG. 18A is a cross-sectional view of the solid state light emitting component 191 of FIG. 17A supported by a secondary reflector base 201 and arranged within a cavity 208 of a secondary reflector structure 200. The secondary reflector structure 200 includes sloping walls 202 having a reflective inner surface 205, with the sloping walls 202 defining an inner diameter that generally increases with distance away from the secondary reflector base 201. The secondary reflector structure 200 is configured to cause light generated by the solid state light emitting component in a lateral direction to be redirected in an upward direction (generally perpendicular to the secondary reflector base 201), as shown in FIG. 18B, which is a modeled ray trace diagram showing a pattern of light beams produced by the solid state light emitting device and secondary reflector structure of FIG. 18A.

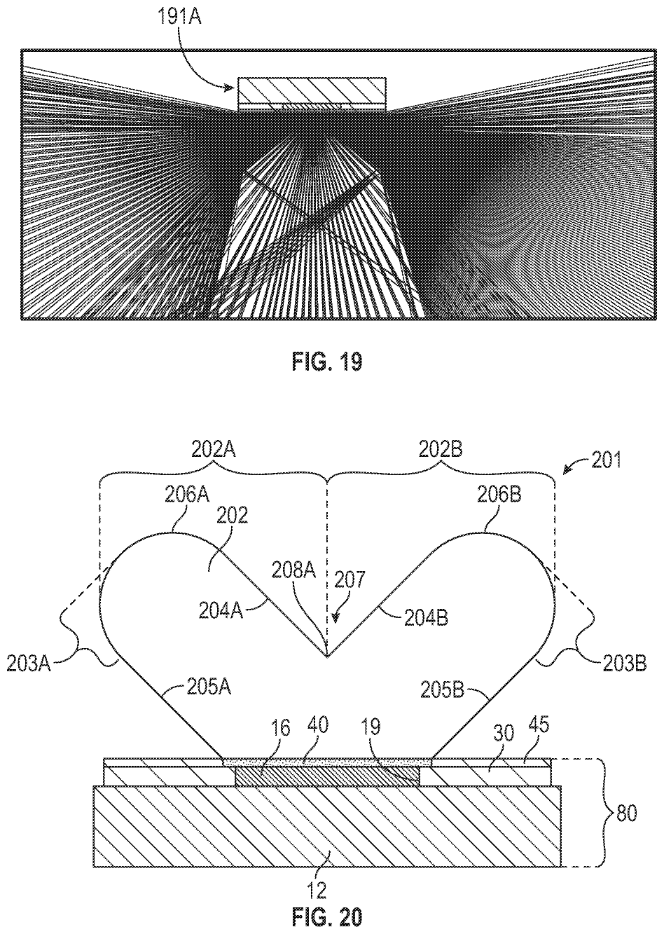

The shape and relative proportions of a lens structure and any corresponding recess(es) of a light emitting component may affect a pattern of light exiting the light emitting component. For example, FIG. 19 is a modeled ray trace diagram showing a pattern of light beams produced by a solid state light emitting device 191A similar to the light emitting component 191 of FIG. 17A, but with the solid state light emitting device 191A being stretched in width (and positioned to emit light in a downward direction). When comparing FIG. 19 to FIG. 17B, it can be seen that stretching the lens structure in width changes a greater proportion of light to be cast in the lateral direction, with a different pattern of light rays being transmitted through a recess defined in a lens structure of the solid state light emitting device 191A.

FIG. 20 illustrates a solid state light emitting component 201 according to one embodiment, including a unitary lens structure 202 defining a recess 207 shaped as a trench between two lobes 202A, 202A forming an upper (or second) portion of the lens structure 202. A lower (or first) portion of the lens structure 202 is bounded by peripheral wall surfaces 205A, 205B configured to produce TIR of emissions generated by an emissive center of a solid state emitter encompassing the LED chip 16 and the lumiphoric material layer 40 within a base structure or subassembly 80 of the solid state light emitting component 201. The solid state light emitting component 201 includes the same base structure or subassembly 80 introduced in FIG. 6, wherein prior descriptions of all components of the base structure or subassembly 80 are incorporated by reference with respect to FIG. 20. A lower portion of the lens structure 201 has a width that increases with distance away from the LED chip 16. The trench-shaped recess 207 is bounded by sloping wall surfaces 204A, 204B that meet at a nadir 208 of the recess 207, wherein the sloping wall surfaces 204A, 204B may be configured to produce TIR of emissions generated by an emissive center of the LED chip 16 and lumiphoric material layer 41. A distal portion 203A, 203B of each lobe 202A, 202A is terminated by a light extraction surface 206A, 206B having an outwardly curved profile. During operation of the light emitting component 201, emissions generated by the LED chip 16 are impinged on the lumiphoric material layer 40 (with such emissions being reflected by the fill material layers 30, 45) and emitted into the lens structure 201. At least portions of emissions emanating from the LED chip 16 and the lumiphoric material layer 40, and incident on (A) the peripheral wall surfaces 205A, 205B and/or the sloping wall surfaces 204A, 204B are reflected outward toward the light extraction surfaces 206A, 206B of the lobes 202A, 202B, through which light exits to a surrounding environment.

In certain embodiments, a unitary lens structure of a light emitting component may include a compound index portion arranged over a light spreading portion, with the compound index portion comprising a first region having a first index of refraction and a second region having a second index of refraction that differs from the first index of refraction, the first region covering less than an entirety of the light spreading portion.

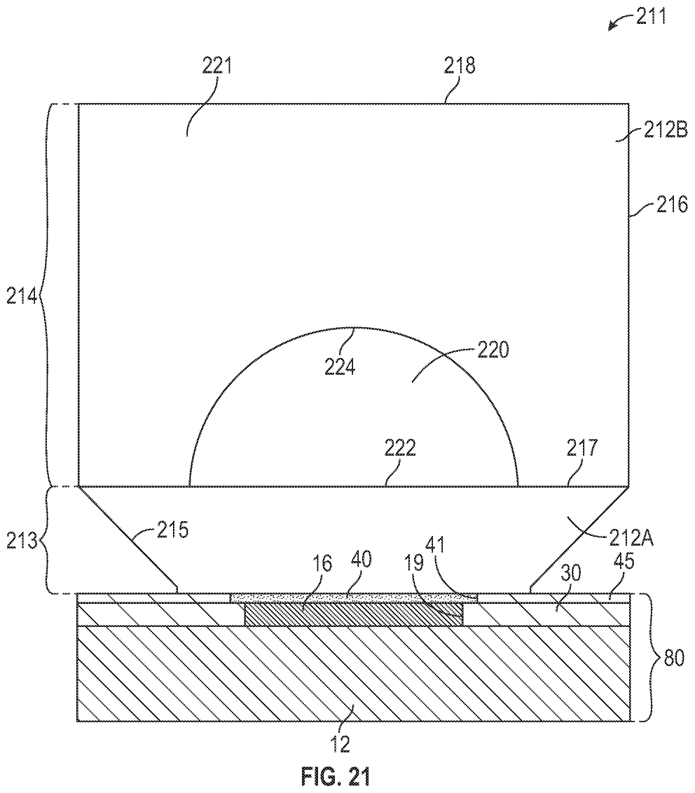

FIG. 21 illustrates a solid state light emitting component 211 according to one embodiment, including a lens structure (212, incorporating at least lens constituents 212A, 212B) with a compound index portion 214 (having first and second regions 220, 221 of refractive indices differing by at least 0.1, 0.2, 0.3, 0.4, 0.5, or some other threshold) arranged over a light spreading portion 213, which is arranged over a base structure or subassembly 80. The solid state light emitting component 211 includes the same base structure or subassembly 80 introduced in FIG. 6, wherein prior descriptions of all components of the base structure or subassembly 80 are incorporated by reference with respect to FIG. 21. The light spreading portion 213 has a width that increases with distance away from the LED chip 16, and is bounded by at least one peripheral wall surface 215 configured to produce TIR of emissions generated by an emissive center of a solid state emitter encompassing the LED chip 16 and the lumiphoric material layer 40. The light spreading portion 213 contacts the compound index portion 214 at an inter-region interface 217, wherein the first region 220 of the compound index portion 214 covers less than an entirety of the light spreading portion 213. As shown, the compound index portion 220 may have a flat surface 222 at the interface 217 (at which the first and second regions 220, 221 contact the light spreading region 213), and a hemispherical (or other curved) surface 224 may be provided as an inter-region interface between the first and second regions 220, 221. The second region 221 has lateral surfaces 216 and an upper surface 218, wherein the foregoing surfaces 216, 218 may embody light extraction surfaces of the light emitting component 211. In certain embodiments, the light spreading portion 213 comprises a first solid material, the second region 221 of the compound index portion 214 comprises a second solid material (which may be the same as or different from the first solid material), and the first region 220 of the compound index portion 214 comprises a gaseous, liquid, or solid material. In certain embodiments, the first and second solid materials comprise silicone, and the first region 220 comprises air. During operation of the light emitting component 211, emissions generated by the LED chip 16 are impinged on the lumiphoric material layer 40 (with such emissions being reflected by the fill material layers 30, 45) and emitted into the light spreading portion 213. At least a portion of emissions emanating from an emissive center of the LED chip 16 and the lumiphoric material layer 40, and incident on the at least one peripheral wall surface 215 is reflected upward toward the compound index portion 214. A central portion of the upwardly-reflected light may enter the first index region 220 and be refracted through the inter-region interface 224 into the second index region 221, while a peripheral portion of the upwardly-reflected light may enter directly into the second index region 221. Light traversing through the second index region 221 exits through light extraction surfaces 216, 218 to a surrounding environment.

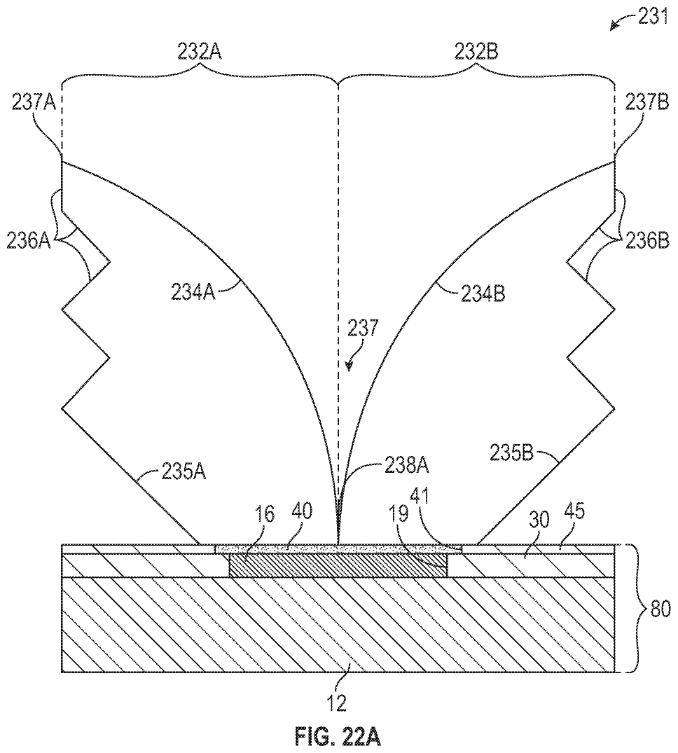

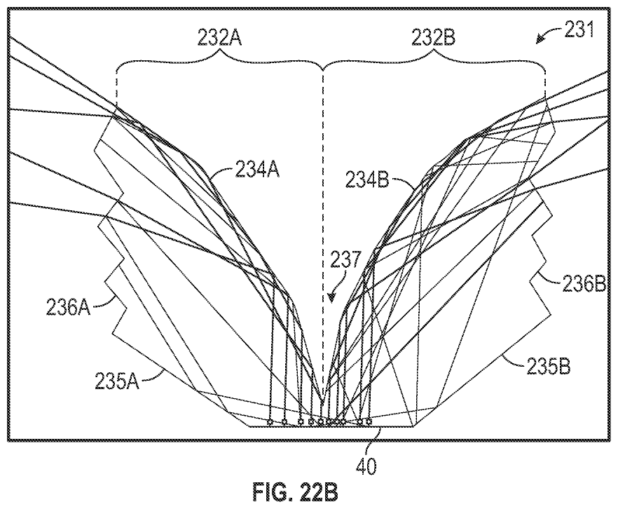

FIG. 22A illustrates a solid state light emitting component 231 according to another embodiment in which a unitary lens structure 212 (composed of lens portions or lobes 212A, 212) defines a central recess 237, with each lobe 212A, 212B having a proximal peripheral wall surface 235A, 235B, distal peripheral light extraction surfaces 236A, 236B providing a sawtooth-shaped profile, and a curved medial wall surface 234A, 234B. Each proximal peripheral wall surface 235A, 235B may having a linear cross-sectional profile is configured to produce TIR (e.g., in an upward direction) of emissions generated by an emissive center of a solid state emitter encompassing the LED chip 16 and the lumiphoric material layer 40. Each curved medial wall surface 234A, 234B is configured to produce TIR (e.g., in a peripheral direction) of emissions generated by an emissive center of the LED chip 16 and the lumiphoric material layer 40, and may also produce TIR of at least some emission reflected upward by the corresponding proximal peripheral wall surface 235A, 235B. The recess 237 is bounded by the curved medial wall surface 234A, 234B and tapers to a nadir 238A proximate to the lumiphoric material 40. In certain embodiments, lens material may remain between the nadir 238A and the lumiphoric material 40. A sharp or curved boundary 237A, 237B may be provided between the light extraction regions 236A, 236B, and curved medial wall surfaces 234A, 234B. During operation of the light emitting component 231, emissions generated by the LED chip 16 are impinged on the lumiphoric material layer 40 (with such emissions being reflected by the fill material layers 30, 45) and emitted into a lower portion of the lobes 232A, 232B. Low angle portions of emissions emanating from the LED chip 16 and the lumiphoric material layer 40 and incident on the proximal peripheral wall surfaces 235A, 235B may be reflected in a generally upward direction toward the light extraction regions 236A, 236B to exit to a surrounding environment. High angle portions of emissions emanating from the LED chip 16 and the lumiphoric material layer 40, as well as portions of light (if any) reflected by the proximal peripheral wall surfaces 235A, 235B, are also reflected in a generally peripheral direction toward the toward the light extraction regions 236A, 236B to exit to a surrounding environment.

FIG. 22B is a first modeled ray trace diagram showing a low-density pattern of selected light beams produced by the solid state light emitting device of FIG. 22A. As shown, Low angle portions of emissions emanating from the LED chip 16 and the lumiphoric material layer 40 and incident on the proximal peripheral wall surfaces 235A, 235B are reflected in a generally upward direction toward the light extraction regions 236A, 236B to exit the lighting component 231, while high angle portions of emissions emanating from the LED chip 16 and the lumiphoric material layer 40 are reflected in a generally peripheral direction toward the light extraction regions 236A, 236B to exit the lighting component 231.

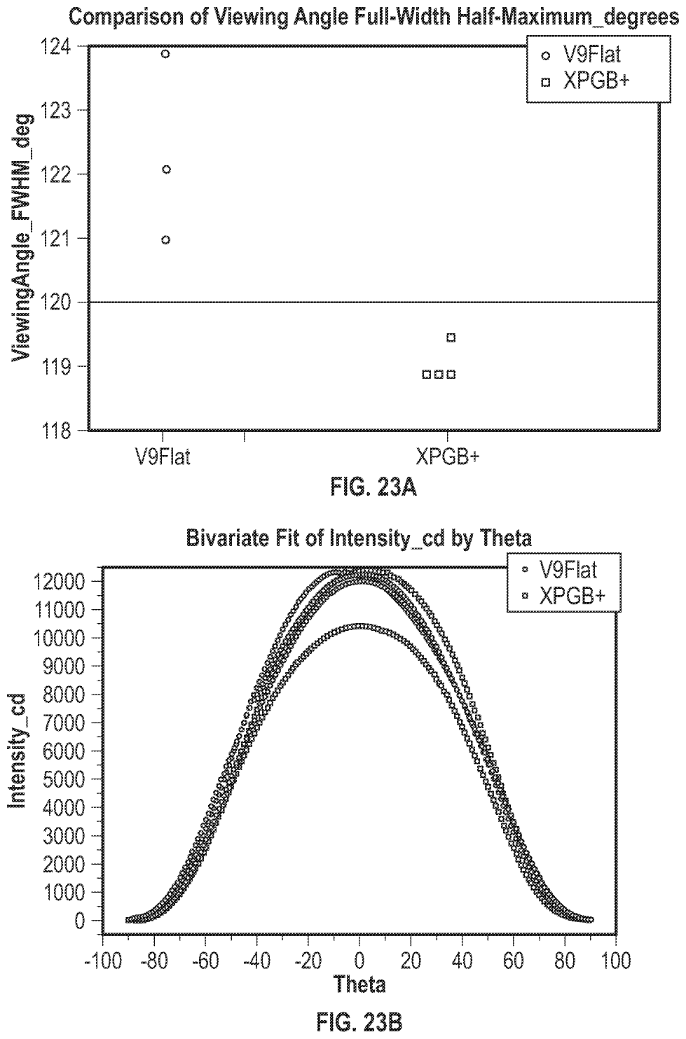

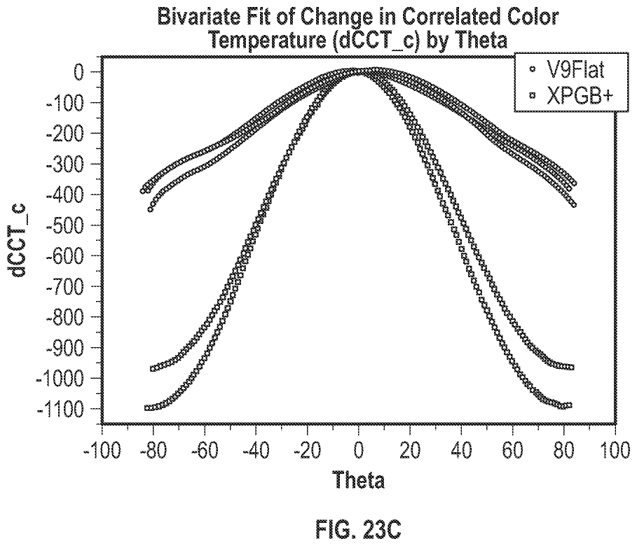

FIG. 23A provides plots of viewing angle (full width at half maximum degrees) for multiple samples of a solid state light emitting device (“V9Flat”) having a flat lens, reflector cavity, LED chip, and lumiphoric material arrangement according to FIG. 5, and for multiple samples of a comparison device (“XPGB+”) having a hemispherical lens arrangement deposited on a base structure including lumiphoric material arranged on lateral edge surfaces of a LED chip and between a submount and a reflective fill material (similar to FIG. 1). As shown, viewing angles are similar for the respective device designs.

FIG. 23B provides bivariate fits of intensity (in candela) as a function of viewing angle (theta) for the same solid state light emitting devices and comparison devices of FIG. 23A. As shown, intensity over viewing angle values are similar for the respective device designs.

FIG. 23C provides bivariate first of change in correlated color temperature (dCCT_c) as a function of viewing angle (theta) for the same solid state light emitting devices and comparison devices of FIG. 23A. As shown, the V9Flat design exhibits significantly more uniform color properties with respect to viewing angle, since the XPGB+ design exhibits greater change in color point with change in viewing angle.

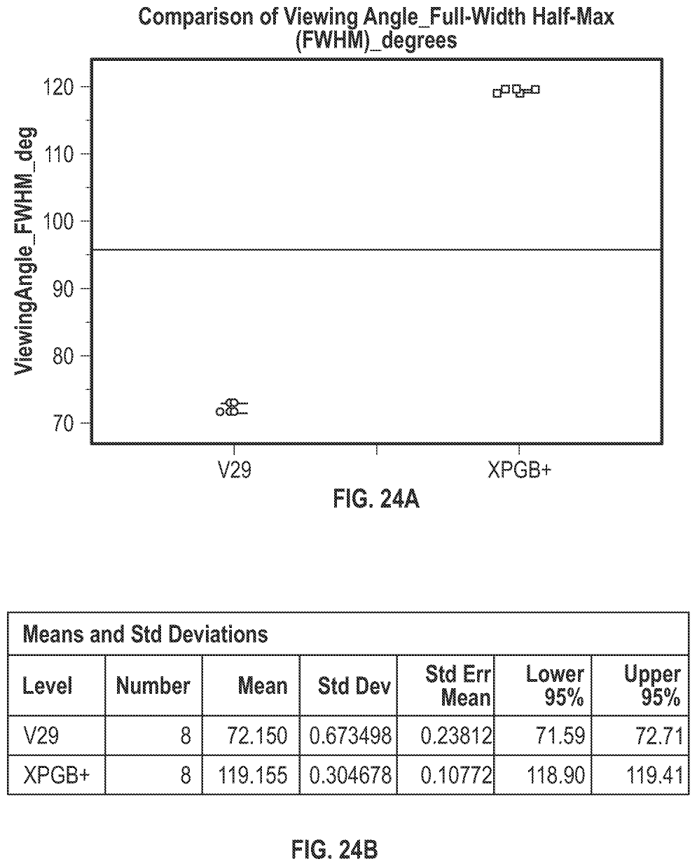

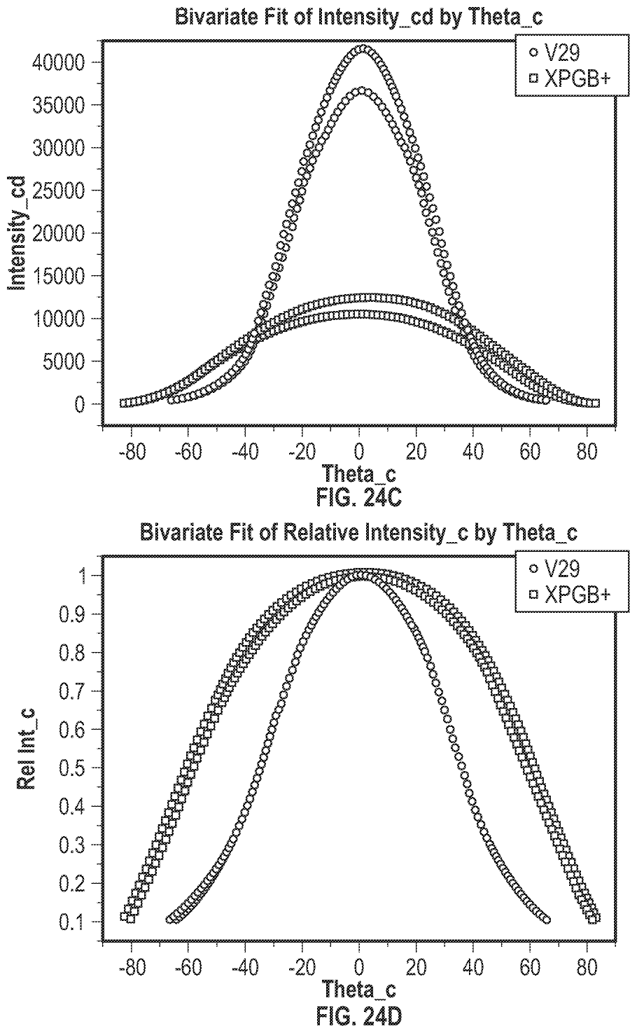

FIG. 24A is provides plots of viewing angle (full width at half maximum degrees) for multiple samples of a solid state light emitting device (“V29”) according to FIG. 11A, and for multiple samples of a comparison device (“XPGB+”) having a similar lens arrangement but including lumiphoric material arranged on lateral edge surfaces of a LED chip and between a submount and a reflective fill material (similar to FIG. 1). FIG. 24B further provides viewing angle mean and standard deviation values for the devices of FIG. 24A. FIGS. 24A and 24B show that, relative to the comparison devices, the V29 devices (including lens structures configured to provide TIR) have substantially tighter viewing angles (with mean values of about 72 versus about 119). This difference in viewing angle is believed to the mainly attributable to the selected non-unitary lens structure (which is non-Lambertian) of the V29 devices. Consistent with the foregoing, in certain embodiments, a non-Lambertian unitary lens structure of a solid state lighting component (which may or may not provide TIR depending on the embodiment) is configured to shape light emissions received from at least one solid state light emitter to produce focused output emissions having an intensity distribution over an angular range with a FWHM value in a range of less than 100, or less than 90, or less than 80, or less than 70, or less than 60, or between 40 and 100, or within a range of 45 and 95, or within a range of 50 to 90, or within a range of 55 to 85, or within a range of 60 to 90, or within a range of 60 to 80, or within a range of 65 to 80, or within a range having upper and lower endpoints of any of the foregoing values.

FIG. 24C provides bivariate fits of intensity (in candela) as a function of viewing angle (theta) for the same solid state light emitting devices and comparison devices of FIG. 24A. FIG. 24D provides bivariate fits of relative intensity (dimensionless) as function of viewing angle (theta) for the foregoing devices, derived from the intensity data plotted in FIG. 24C. FIG. 24C shows that the V29 devices exhibit significantly greater peak intensity, while FIGS. 24C and 24D show that the V29 devices exhibit a greater drop in intensity with change in viewing angle.

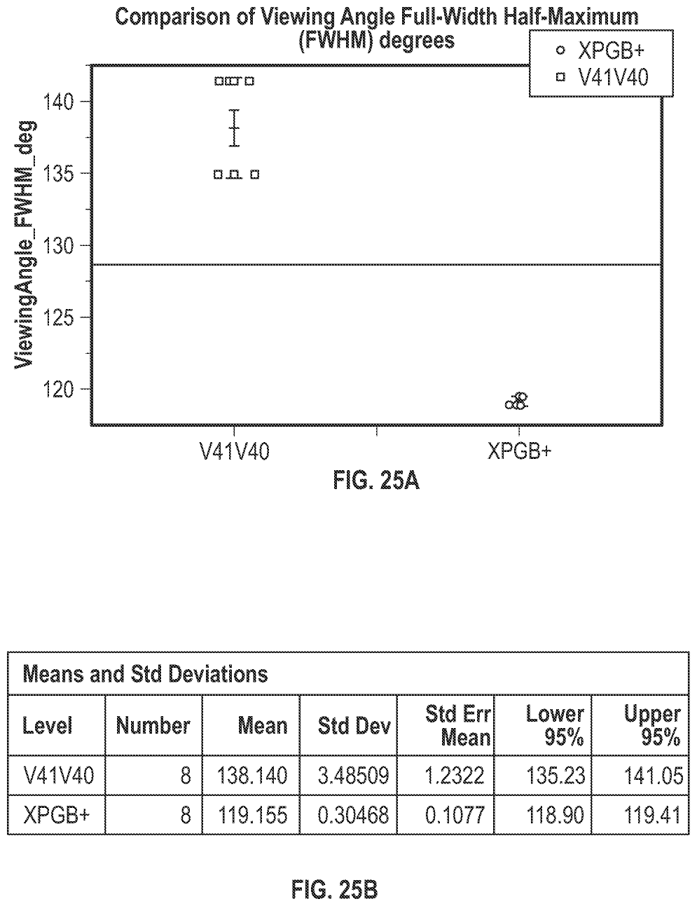

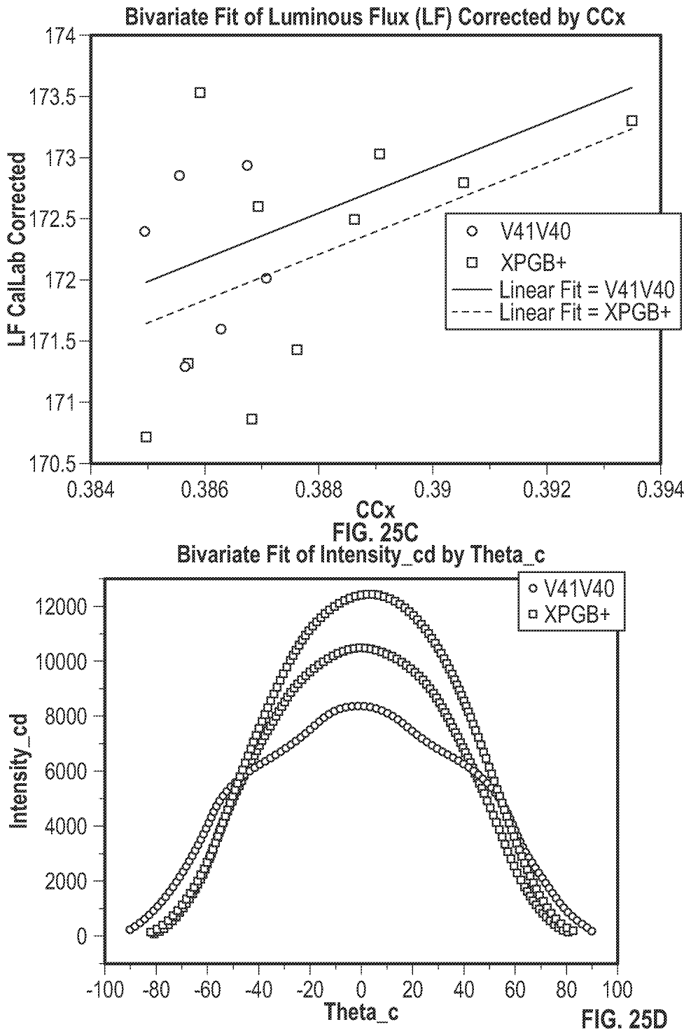

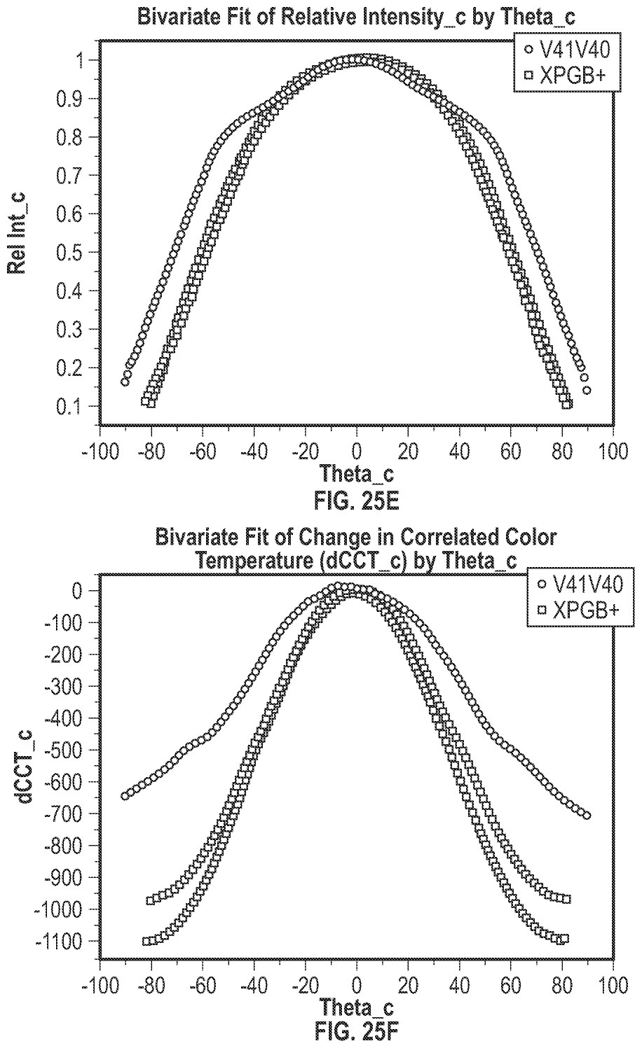

FIG. 25A is provides plots of viewing angle (full width at half maximum degrees) for multiple samples of solid state light emitting devices (“V41V40”) having an outwardly curved lens and lumiphoric material arrangement according to FIG. 7A, and for multiple samples of a comparison device (“XPGB+”) having a similar lens arrangement but including lumiphoric material arranged on lateral edge surfaces of a LED chip and between a submount and a reflective fill material (similar to FIG. 1). FIG. 25B further provides viewing angle mean and standard deviation values for the same solid state light emitting devices and comparison devices of FIG. 25A. FIGS. 25A and 25B show that, relative to the comparison devices, the V4140 devices have wider viewing angles (with mean values of about 138 versus about 119). This difference in viewing angle is believed to the mainly attributable to the selected non-unitary lens structure (which is non-Lambertian) of the V4140 devices. Consistent with the foregoing, in certain embodiments, a non-Lambertian unitary lens structure of a solid state lighting component is configured to shape light emissions received from at least one solid state light emitter to produce focused output emissions having an intensity distribution over an angular range with a FWHM value in a range of greater than 130, or greater than 135, or greater than 140, or greater than 150, or greater than 160, or greater than 170, or within a range of 130 to 200, or within a range of 140 to 200, or within a range of 150 to 200, or within a range of 130 to 190, or within a range of 140 to 190, or within a range of 150 to 190, or within a range of 130 to 180, or within a range of 140 to 180, or within a range of 150 to 180, or within a range having upper and lower endpoints of any of the foregoing values.

FIG. 25C provides bivariate fits of luminous flux corrected by color point (CCx) for the same solid state light emitting devices and comparison devices of FIG. 25A, showing that luminous flux corrected by color point (CCx) values for the V4140 devices and the XPGB+ devices are similar.

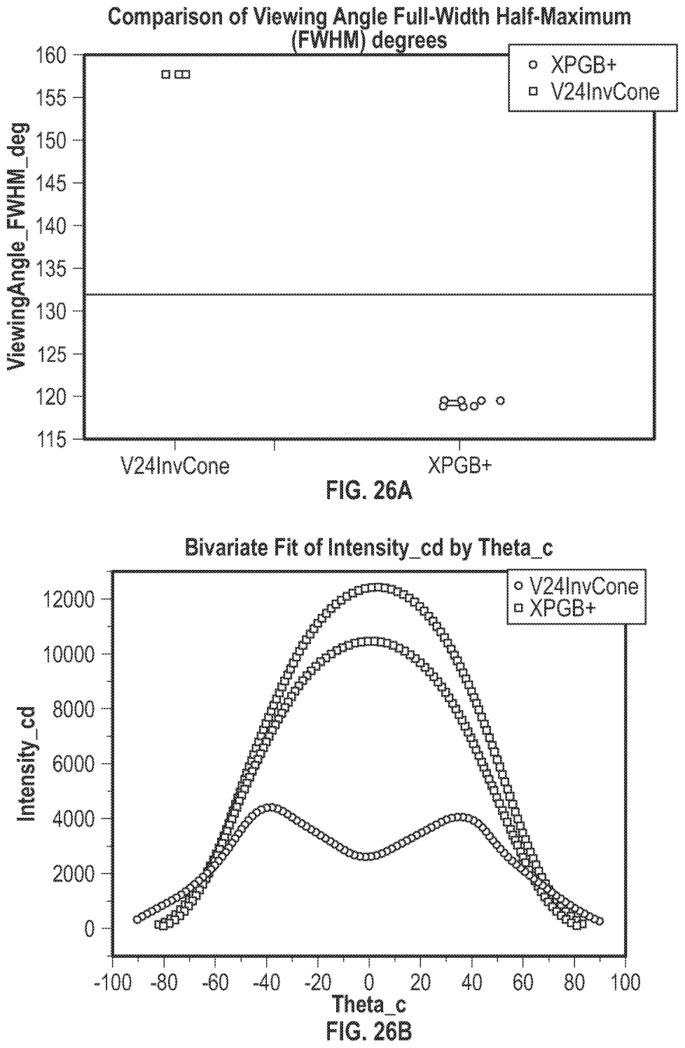

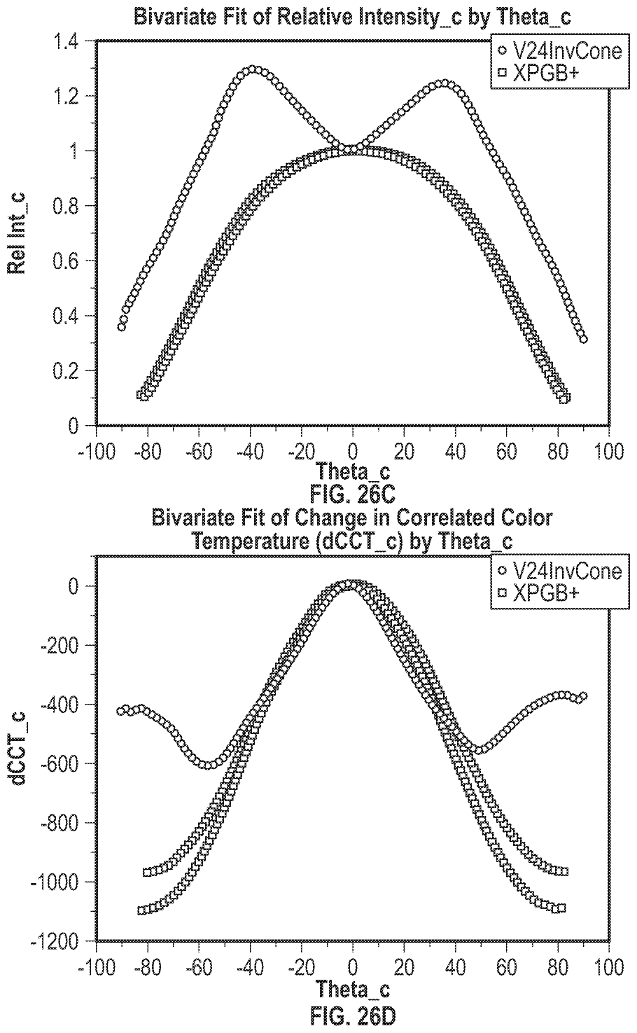

FIG. 25D provides bivariate fits of intensity (in candela) as a function of viewing angle (theta) for the same solid state light emitting devices and comparison devices of FIG. 25A. FIG. 25E provides bivariate fits of relative intensity (dimensionless) as function of viewing angle (theta) for the foregoing devices, derived from the intensity data plotted in FIG. 26D. FIG. 25D shows that the V4140 devices exhibit significantly greater peak intensity, while FIGS. 25D and 25E show that the V4140 devices exhibit a lesser drop in intensity with change in viewing angle.

FIG. 25F provides bivariate fits of change of correlated color temperature (dCCT_c) as function of viewing angle (theta) for the same solid state light emitting devices and comparison devices of FIG. 25A. FIG. 25F shows that the V4140 design exhibits more uniform color properties with respect to viewing angle, since the XPGB+ design exhibits greater change in color point with change in viewing angle.

Although FIGS. 25A-25F provide data for devices having greater viewing angle than XPGB+ comparison devices, further devices having even higher viewing angle properties are characterized in FIGS. 26A-26D.

FIG. 26A provides plots of viewing angle (full width at half maximum degrees) for multiple samples of solid state light emitting devices (“V241nvCone”) having a conical shaped recess defined in a unitary lens arranged over a LED chip and lumiphoric material arrangement according to FIG. 17A, and for multiple samples of a comparison device (“XPGB+”) having a similar lens arrangement but including lumiphoric material arranged on lateral edge surfaces of a LED chip and between a submount and a reflective fill material (similar to FIG. 1). FIG. 26A shows that, relative to the comparison devices, the V4140 devices have wider viewing angles (with mean values of about 158 versus about 119). This difference in viewing angle is believed to the mainly attributable to the selected non-unitary lens structure (which is non-Lambertian) of the V241nvCone devices.

FIG. 26B provides bivariate fits of intensity (in candela) as a function of viewing angle (theta) for the same solid state light emitting devices and comparison devices of FIG. 26A. FIG. 26C provides bivariate fits of relative intensity (dimensionless) as function of viewing angle (theta) for the foregoing devices. FIGS. 26B and 26C show a unique intensity profile that has a local minimum at a viewing angle value of zero degrees, and while intensity (and relative intensity) rises to local peak values near 40 degrees and −40 degrees, respectively, and then falls with rising angular difference away from the local peaks.

FIG. 26D provides bivariate fits of change of correlated color temperature (dCCT_c) as function of viewing angle (theta) for the same solid state light emitting devices and comparison devices of FIG. 26A. Color point is comparable between the V241nvCone devices and XPGB+ comparison devices for viewing angle values from about −50 to about 50 degrees, but color point for the V241nvCone devices is significantly better for viewing angle values outside this range.

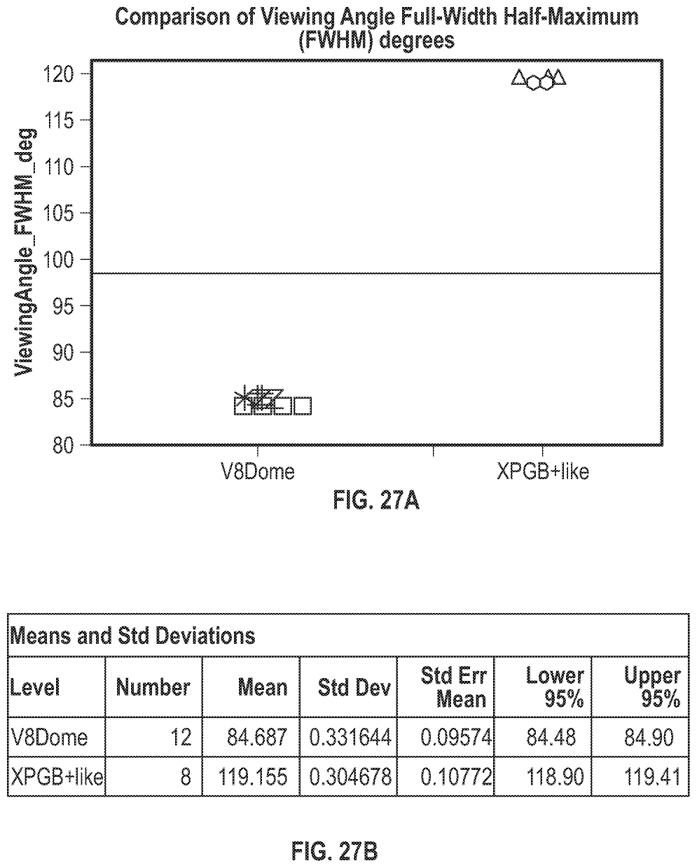

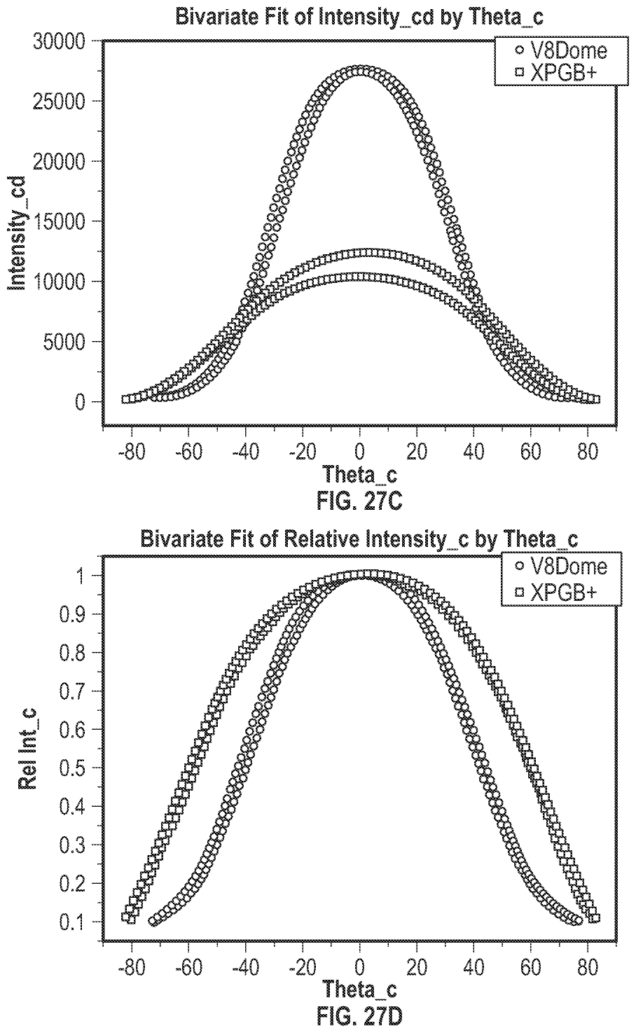

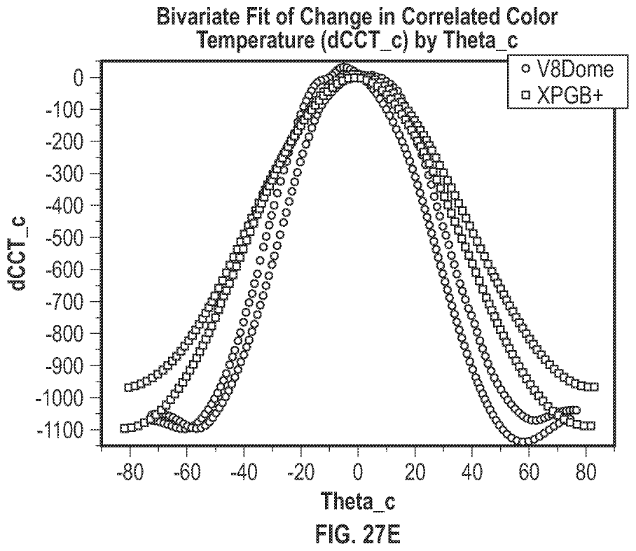

FIG. 27A provides plots of viewing angle (full width at half maximum degrees) for multiple samples of a solid state light emitting device (“V8Dome”) having a hemispherical lens, reflector cavity, LED chip, and lumiphoric material arrangement according to FIG. 4 (i.e., including a lens structure not providing TIR), and for multiple samples of a comparison device (“XPGB+”) having a hemispherical lens arrangement deposited on a base structure including lumiphoric material arranged on lateral edge surfaces of a LED chip and between a submount and a reflective fill material (similar to FIG. 1). FIG. 27B provides viewing angle mean and standard deviation values for the devices characterized in FIG. 27A. FIGS. 27A and 27B show that, relative to the comparison devices, the V8Dome devices (including lens structures not configured to provide TIR) have tighter viewing angles (with mean values of about 85 versus about 119). This difference in viewing angle is believed to the mainly attributable to the selected non-unitary lens structure (which is non-Lambertian) of the V8Dome devices.

FIG. 27C provides bivariate fits of intensity (in candela) as a function of viewing angle (theta) for the same solid state light emitting devices and comparison devices of FIG. 27A. FIG. 27D provides bivariate fits of relative intensity (dimensionless) as function of viewing angle (theta) for the same solid state light emitting devices and comparison devices of FIG. 27A. FIG. 27C shows that the V8Dome devices exhibit significantly greater peak intensity, while FIGS. 27C and 27D show that the V8Dome devices exhibit a greater drop in intensity with change in viewing angle.

FIG. 27E provides bivariate fits of change of correlated color temperature (dCCT_c) as function of viewing angle (theta) for the same solid state light emitting devices and comparison devices of FIG. 27A, showing that change in CCT as a function of viewing angle is comparable between the respective devices, but slightly better for the XPGB+ devices at higher viewing angles.

Embodiments disclosed herein may provide one or more of the following beneficial technical effects: enabling fabrication of compact solid state light emitting devices having desirable beam patterns (e.g., whether highly focused, highly dispersed, or having novel shapes or distributions) without necessarily requiring secondary optics; enabling fabrication of compact solid state light emitting devices exhibiting enhanced luminous efficacy and/or uniformity of color point over emissive area; simplifying fabrication of solid state light emitting devices; and enhancing reliability and service life of high-intensity solid state light emitting devices.

Those skilled in the art will recognize improvements and modifications to the preferred embodiments of the present disclosure. All such improvements and modifications are considered within the scope of the concepts disclosed herein and the claims that follow.

What is claimed is:

1. A solid state light emitting component comprising:
at least one solid state light emitter configured to generate light emissions; and
a unitary lens structure arranged in contact with the at least one solid state light emitter and configured to receive at least a portion of the light emissions generated by the at least one solid state light emitter;
wherein at least a first portion of the unitary lens structure proximate to the at least one solid state light emitter has a width that increases with distance away from the at least one solid state light emitter; and
wherein the at least a first portion of the unitary lens structure comprises at least one inclined or curved surface having an orientation configured to produce total internal reflection of a portion of light emissions originating from an emissive center of the at least one solid state light emitter, and configured to reflect light toward one or more light exit surfaces of the solid state light emitting component.

2. The solid state light emitting component of claim 1, wherein the at least one inclined or curved surface comprises a peripheral edge surface of the at least a first portion of the unitary lens structure.

3. The solid state light emitting component of claim 1, wherein the unitary lens structure defines a recess, and the at least one inclined or curved surface bounds at least a portion of the recess.

4. The solid state light emitting component of claim 1, wherein the unitary lens structure further comprises a second portion having a width that decreases with distance away from the at least one solid state light emitter, wherein the first portion of the unitary lens structure is arranged between the at least one solid state light emitter and the second portion of the unitary lens structure.

5. The solid state light emitting component of claim 1, wherein the unitary lens structure comprises a material having a first index of refraction, the at least a first portion of the unitary lens structure is bounded by an outer lateral lens surface, and the outer lateral lens surface is bounded by a material or space having a second index of refraction, wherein the first index of refraction exceeds the second index of refraction by a value of least 0.4.

6. The solid state light emitting component of claim 1, comprising one of the following features (a) or (b): (a) the at least a first portion of the unitary lens structure comprises an inverted truncated pyramidal shape or an inverted truncated conical shape, or (b) the unitary lens structure comprises a recess shaped as an inverted pyramid, an inverted cone, or a trench, and having a nadir that is registered with the emissive center of the at least one solid state light emitter.

7. The solid state light emitting component of claim 1, further comprising a submount to which the at least one solid state light emitter is mounted, wherein a width of the unitary lens structure is no greater than a width of the submount at a location where the unitary lens structure is arranged in contact with the at least one solid state light emitter.

8. The solid state light emitting component of claim 1, wherein the at least one solid state light emitter comprises a LED chip and a lumiphoric material layer arranged over an outer surface of the LED chip, wherein lateral edge surfaces of the LED chip are devoid of lumiphoric material, and the solid state light emitting component further comprises:
a submount to which the at least one solid state light emitter is mounted; and
a fill material layer comprising fill material and contacting lateral edge surfaces of the at least one solid state light emitter, the fill material comprising white or light-reflective particles dispersed in a binder;
wherein a portion of the lumiphoric material overlaps a portion of the fill material layer.

9. A solid state light emitting component comprising:
at least one solid state light emitter configured to generate light emissions; and
a non-Lambertian unitary lens structure arranged in contact with the at least one solid state light emitter and configured to receive at least a portion of the light emissions generated by the at least one solid state light emitter, wherein the solid state light emitting component is devoid of an air gap through which the light emissions are transmitted into the non-Lambertian unitary lens structure;
wherein the non-Lambertian unitary lens structure is configured to shape light emissions received from the at least one solid state light emitter to produce output emissions having one of the following characteristics (a) or (b):
(a) focused output emissions having an intensity distribution over an angular range with a full width at half maximum (FWHM) value of less than 100; or
(b) dispersed output emissions having an intensity distribution over an angular range with a FWHM value of greater than 130.

10. The solid state light emitting component of claim 9, wherein the non-Lambertian unitary lens structure is configured to shape light emissions received from the at least one solid state light emitter to produce focused output emissions having an intensity distribution over an angular range with a FWHM value in a range between 40 and 100.

11. The solid state light emitting component of claim 9, wherein the non-Lambertian unitary lens structure is configured to shape light emissions received from the at least one solid state light emitter to produce dispersed output emissions having an intensity distribution over an angular range with a FWHM value in a range between 130 and 200.

12. The solid state light emitting component of claim 9, wherein:
at least a first portion of the non-Lambertian unitary lens structure proximate to the at least one solid state light emitter has a width that increases with distance away from the at least one solid state light emitter; and
the at least a first portion of the non-Lambertian unitary lens structure is bounded by a lateral edge surface having an orientation configured to produce total internal reflection of a portion of light emissions originating from an emissive center of the at least one solid state light emitter.

13. The solid state light emitting component of claim 9, wherein:
the at least one solid state light emitter is arranged within a cavity defined by an elevated reflector structure;
at least a first portion of the non-Lambertian unitary lens structure proximate to the at least one solid state light emitter has a width that increases with distance away from the at least one solid state light emitter; and
the at least a first portion of the non-Lambertian unitary lens structure is arranged in contact with a reflective wall of the elevated reflector structure bounding the cavity.

14. The solid state light emitting component of claim 9, further comprising a submount to which the at least one solid state light emitter is mounted, wherein a width of the non-Lambertian unitary lens structure is no greater than a width of the submount at a location where the non-Lambertian unitary lens structure is arranged in contact with the at least one solid state light emitter.

15. The solid state light emitting component of claim 9, wherein the at least one solid state light emitter comprises a LED chip and a lumiphoric material layer arranged over an outer surface of the LED chip, wherein lateral edge surfaces of the LED chip are devoid of lumiphoric material, and the solid state light emitting component further comprises:
a submount to which the at least one solid state light emitter is mounted; and
a fill material layer comprising fill material and contacting lateral edge surfaces of the at least one solid state light emitter, the fill material comprising white or light-reflective particles dispersed in a binder;
wherein a portion of the lumiphoric material overlaps a portion of the fill material layer.

16. A solid state light emitting component comprising:
at least one solid state light emitter arranged over a submount and configured to generate light emissions, the at least one solid state light emitter comprising an outer surface distal from the submount; and
a lens structure arranged over the at least one solid state light emitter and configured to receive at least a portion of the light emissions generated by the at least one solid state light emitter, the lens structure comprising:
a light spreading portion contacting the outer surface of the at least one solid state light emitter; and
a compound index portion arranged over the light spreading portion, the compound index portion comprising a first region having a first index of refraction and a second region having a second index of refraction that differs from the first index of refraction, the first region covering less than an entirety of the light spreading portion.

17. The solid state light emitting component of claim 16, wherein the light spreading portion of the lens comprises a width that increases with distance away from the at least one solid state light emitter, and is laterally bounded by at least one inclined or curved surface having an orientation configured to produce total internal reflection of a portion of light emissions originating from an emissive center of the at least one solid state light emitter and configured to reflect light toward one or more light exit surfaces of the lens structure.

18. The solid state light emitting component of claim 16, wherein the first region of the compound index portion comprises glass or sapphire, or the first region of the compound index portion consists of at least one gas.

19. The solid state light emitting component of claim 16, further comprising a submount to which the at least one solid state light emitter is mounted, wherein a width of the unitary lens structure is no greater than a width of the submount at a location where the unitary lens structure is arranged in contact with the at least one solid state light emitter.

20. The solid state light emitting component of claim 16, wherein the at least one solid state light emitter comprises a LED chip and a lumiphoric material layer arranged over an outer surface of the LED chip, wherein lateral edge surfaces of the LED chip are devoid of lumiphoric material, and the solid state light emitting component further comprises:
a submount to which the at least one solid state light emitter is mounted; and
a fill material layer comprising fill material and contacting lateral edge surfaces of the at least one solid state light emitter, the fill material comprising white or light-reflective particles dispersed in a binder;
wherein a portion of the lumiphoric material overlaps a portion of the fill material layer.
